(19) United States
(12) Patent Application Publication
(10) Pub. No.: US 2025/0028245 A1
(43) Pub. Date: Jan. 23, 2025

(54) POSITIVE TONE ULTRA THICK PHOTORESIST COMPOSITION

(71) Applicant: Merck Patent GmbH, Darmstadt (DE)

(72) Inventors: Weihong LIU, Branchburg, NJ (US); Chunwei CHEN, Whitehouse Station, NJ (US)

(21) Appl. No.: 18/702,064

(22) PCT Filed: Nov. 15, 2022
(86) PCT No.: PCT/EP2022/081927

§ 371 Date: Apr. 17, 2024

Related U.S. Application Data
(60) Provisional application No. 63/280,295, filed on Nov. 17, 2021.

(51) Int. Cl. G03F 7/039; C08L 33/10; C08L 59/00; G03F 7/004

(52) U.S. Cl. CPC G03F 7/0397; C08L 33/10; C08L 59/00; G03F 7/0045; C08L 2205/03

(57) ABSTRACT

A positive working chemically amplified photosensitive composition comprising: Component a) at least one random copolymer, having structure (A), component b) at least one acrylic polymer component of structure (B) comprising repeat units selected from ones having structure (1), (2), (3), (4), (5), (6), and (7); component c) at least one Novolak polymer; component d) at least one photoacid generator (PAG); component c) at least one base additive; component f) at least one heterocyclic thiol compound; and component g) an organic spin casting solvent.

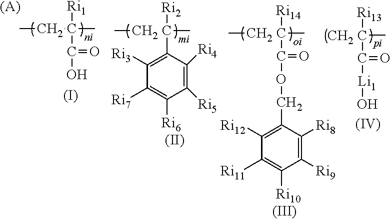

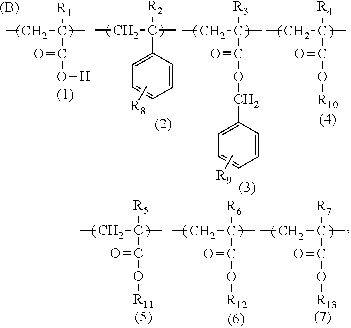

### FIELD

The disclosed subject matter pertains to a positive radiation-sensitive aqueous base soluble photoresist composition used for making integrated circuit (IC), light emitting diode (LED) devices and display devices.

### BACKGROUND

Photoresist compositions are used in microlithographic processes for making miniaturized electronic components such as in the fabrication of computer chips, integrated circuits, light emitting diode (LED) devices and displays. Generally, in these processes, a film of a photoresist composition is first applied to a substrate material, such as silicon wafers used for making integrated circuits. The coated substrate is then baked to evaporate solvent in the photoresist composition and to fix the coating onto the substrate. The baked, coated surface of the substrate is next subjected to an image-wise exposure to imaging radiation.

This radiation exposure causes a chemical transformation in the exposed areas of the coated surface. Visible light, ultraviolet (UV) light, electron beam and X-ray radiant energy are imaging radiation types commonly used today in microlithographic processes. After this image-wise exposure, the coated substrate is treated with a developer solution to dissolve and remove either the radiation-exposed or the unexposed arcas of the coated surface of the substrate.

There are two types of photoresist compositions, negative-working and positive-working. When positive-working photoresist compositions are exposed image-wise to radiation, the areas of the resist composition exposed to the radiation become more soluble to a developer solution (e.g., release of base solubilizing group or photo-decomposition of dissolution inhibitor), while the unexposed areas of the photoresist coating remain relatively insoluble to such a solution. Thus, treatment of an exposed positive-working resist with a developer causes removal of the exposed areas of the photoresist coating and the creation of a positive image in the coating, thereby uncovering a desired portion of the underlying substrate surface on which the photoresist composition was deposited.

The use of a positive-working, sensitive photoresist composition which is developable by aqucous base is known. Most of these compositions are either chemically amplified photoresists based on either phenolic or (meth)acrylate resin or non-chemically amplified photoresists based on Novolak/diazonaphthoquinone (DNQ). In a Novolak/DNQ photoresist a positive image is formed through the photodecomposition of the diazonaphthoquinone compound (PAC) which in resist areas exposed leads to a faster dissolution of the Novolak resin in aqueous base, these types of photoresists are employed at longer UV wavelengths such as i-line (365 nm) and were for many years workhorse photoresists in the manufacturing of integrated circuits (IC).

Semiconductor assembly process has been improved by wafer level packaging (WLP) introduction in high volume manufacturing copper (Cu)-Redistribution layer (RDL) miniaturization is one of key process for small, thin, and light chip manufacturing. Fine pitch redistribution layer (RDL) is the market trend for high density wafer level fan-out (HDWLFO) packaging for semiconductors. Photoresist development with high resolution and transmittance is required to this technology realization on the topology substrate. Chemical amplified (CA) type photoresist indicated stable sensitivity and high resolution at various thickness because of its high transparency at i-line (365 nm) exposure. However, high price and poor environment stability limit its application in RDL fabrication for outsourced semiconductor assembly and test (OSAT) companies.

One problem associated with thick chemically amplified photoresist formulations thicker than 150 microns is wetting on substrates which results in profiles in imaged films which are not vertical. Another problem associated with these thick chemically amplified photoresist is that the processing time is much longer because of lack of sensitivity and low dissolution rates which has negative impact on the throughput of IC manufacturing techniques which employ such thick chemically amplified photoresists. Thus, there is a need for a thick chemically amplified photoresist formulation which avoids these problems. Further there is a need in thick photoresists used in lithographic process such as metal plating for a thick photoresist which also shows better wetting on substrates.

### SUMMARY

In order to meet requirements for improving profiles in semiconductor manufacturing employing thick chemically amplified photoresists, improving wetting of these material and keeping patterns imaged with these vertical while maintaining a very small amount of dark erosion of less than 1 micron, and avoiding the problem of decreased wafer throughput, new thick chemically amplified photoresist formulations were developed which have high resolution, with good photosensitivity, good dissolution rates, which show vertical pattern profiles and give good wetting on substrates. These disclosed novel thick photoresist formulations are comprised of two copolymeric components, one of which comprises repeat units derived from an acrylic acid, and the other copolymeric component is an acrylate copolymer which comprises an acrylate derivative with an acid cleavable group and a repeat unit derived from a benzylic acrylate, a styrene, or a mixture of a benzylic acrylate and a styrene, as follows:

In one aspect the novel positive working chemically amplified photosensitive composition comprises the following component:

Component a) is at least one random copolymer, having structure (A), wherein
the repeat unit of structure (I) ranges from about 17 mole % to about 70 mole %,
the repeat unit of structure (II) ranges from 0 to about 70 mole %,
the repeat unit of structure (III) ranges from 0 to about 70 mole %,
the sum of the repeat unit of structures (II) and (III) ranges from about 30 mole % to about 70 mole %,
the repeat unit of structure (IV) ranges from about 0 mole % to about 35 mole %, wherein the sum of the mole % of the repeat units of structure (I), (II), (III), and (IV) either does not exceed 100 mole % or is equal to 100 mole %, if other types of repeat units are not present, Ri₁, Ri₂, Ri₁₄ and Ri₁₃ are individually selected from H or a C-1 to C-4 alkyl, Ri₃, Ri₄, Ri₅, Ri₆, Ri₇, Ri₈, Ri₉, Ri₁₀, Ri₁₁, and Ri₁₂, are individually selected from H, a C-1 to C-8 alkyl, a C-1 to C-4 alkoxy, a phenyl, a substituted phenyl, and mixtures thereof, Li₁ is a C-2 to C-6 alkylene moiety, ni, mi, oi and pi are respectively the number of repeat units of structure (I), (II), (III) and (IV), and further wherein, the copolymer of structure (A) has a minimum dissolution rate of 500 Å/sec in 0.26 N tetramethylammonium hydroxide at 23° C., and does not comprise any repeat units which have acid cleavable groups;

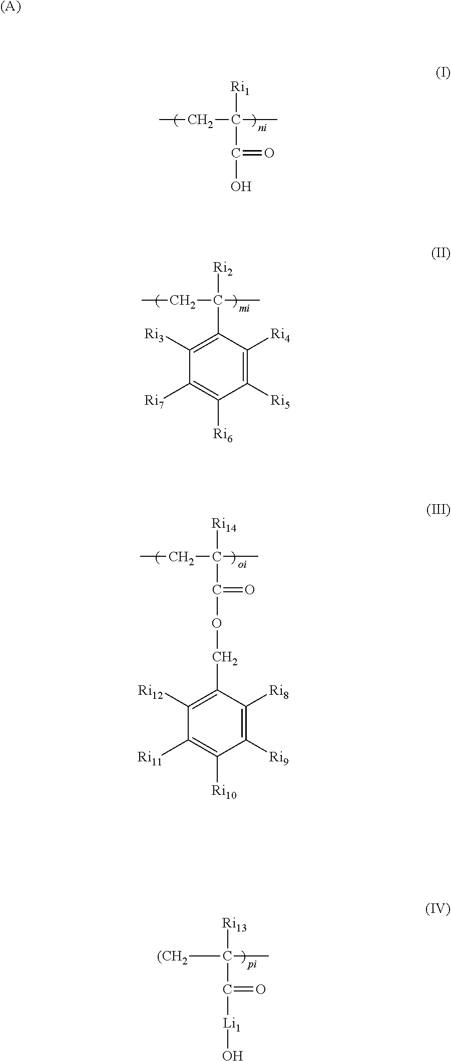

component b) at least one acrylic copolymer component of structure (B) comprising repeat units selected from ones having structure (1), (2), (3), (4), (5), (6), and (7): wherein R₁, R₂, R₃, R₄, R₅, R₆, and R₇ are individually selected from either H, F, a C-1 to C-4 perfluoroalkyl, or a C-1 to C-4 alkyl,
R₈ and R₉ are individually selected from H, a C-1 to C-4 alkyl, a C-1 to C-4 alkyloxy alkyl, and a halogen,
R₁₀ is selected from the group consisting of a C-1 to C-8 primary alkyl, a C-3 to C-8 secondary alkyl, a C-3 to C-8 cyclic secondary alkyl, and a C-7 to C-14 secondary alicyclic alkyl,
R₁₁ is a C-2 to C-8 (hydroxy)alkylene moiety,
R₁₂ is a tertiary alkyl acid cleavable group, and
R₁₃ is a C-3 to C-12 (alkyloxy)alkylene moiety; and further
these repeat units in total constitute 100 mole % of the repeat units in said functionalized acrylic copolymer, where,
the repeat unit of structure (1) ranges from about 0 mole % to about 20 mole %,
the repeat unit of structure (2) ranges from about 0 mole % to about 20 mole % of the acrylic copolymer,
wherein the repeat unit of structure (3) ranges from about 5 mole % to about 55 mole % of the acrylic copolymer,
wherein the repeat unit of structure (4) ranges from about 0 mole % to about 30 mole % of the acrylic copolymer,
the repeat unit of structure (5) ranges from about 15 mole % to about 55 mole % of the acrylic copolymer,
the repeat unit of structure (6) ranges from about 18 mole % to about 40 mole % of the acrylic copolymer
the repeat unit of structure (7) ranges from about 0 mole % to about 40 mole % of the acrylic copolymer

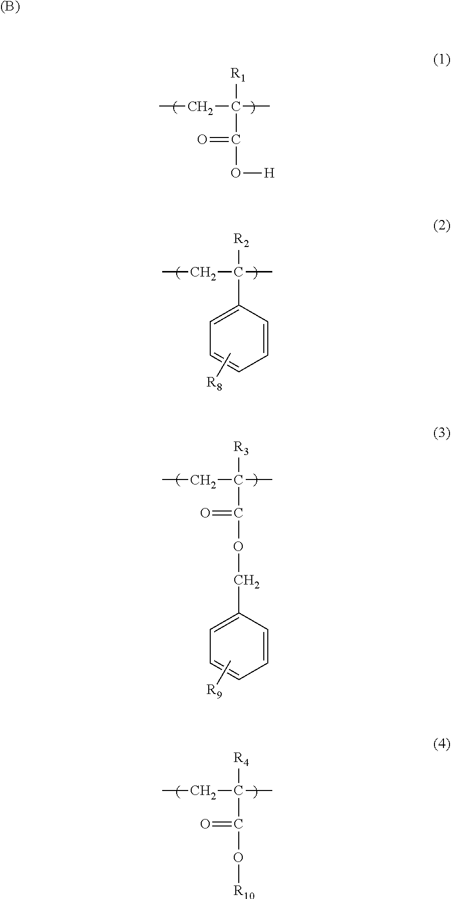

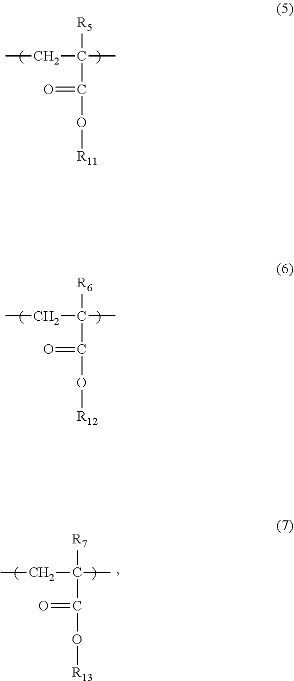

component c) at least one Novolak polymer,
component d) at least one photoacid generator (PAG),
component e) at least one base additive,
component f) at least one heterocyclic thiol compound,
component g) an organic spin casting solvent.

The disclosed subject matter also pertains to the method of coating the resist compositions on a substrate as part of a lithographic process.

### BRIEF DESCRIPTION OF THE FIGURES

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter.

FIG. 1 Lithographic performance of Comparative Formulation.

FIG. 2 Lithographic performance of Formulation 7.

### DETAILED DESCRIPTION

It is to be understood that both the foregoing general description and the following detailed description are illustrative and explanatory and are not restrictive of the subject matter as claimed. In this application, the use of the singular includes the plural, the word “a” or “an” means “at least one,” and the use of “or” means “and/or,” unless specifically stated otherwise. Furthermore, the use of the term “including,” as well as other forms such as “includes” and “included,” is not limiting. Also, terms such as “element” or “component” encompass both elements and components comprising one unit and elements or components that comprise more than one unit, unless specifically stated otherwise. As used herein, the conjunction “and” is intended to be inclusive and the conjunction “or” is not intended to be exclusive unless otherwise indicated. For example, the phrase “or, alternatively” is intended to be exclusive. As used herein, the term “and/or” refers to any combination of the foregoing elements including using a single element.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature references and similar materials defines a term in a manner that contradicts the definition of that term in this application, this application controls.

Unless otherwise indicated, “alkyl” refers to hydrocarbon groups which can be linear, branched (e.g., methyl, ethyl, propyl, isopropyl, tert-butyl and the like) or cyclic (e.g., cyclohexyl, cyclopropyl, cyclopentyl and the like) multicyclic (e.g., norbornyl, adamantly and the like). These alkyl moieties may be substituted or unsubstituted as described below. The term “alkyl” refers to such moieties with C-1 to C-20 carbons. It is understood that for structural reasons lincar alkyls start with C-1, while branched alkyls and cyclic alkyls start with C-3 and multicyclic alkyls start with C-5. Moreover, it is further understood that moieties derived from alkyls described below, such as alkyloxy and haloalkyloxy, have the same carbon number ranges unless otherwise indicated. If the length of the alkyl group is specified as other than described above, the above-described definition of alkyl still stands with respect to it encompassing all types of alkyl moieties as described above and that the structural consideration with regards to minimum number of carbons for a given type of alkyl group still apply.

Alkyloxy (a.k.a. Alkoxy) refers to an alkyl group on which is attached through an oxy (—O—) moiety (e.g., methoxy, ethoxy, propoxy, butoxy, 1,2-isopropoxy, cyclopentyloxy cyclohexyloxy and the like). These alkyloxy moieties may be substituted or unsubstituted as described below.

Halo or halide refers to a halogen, F, Cl, Br or I which is linked by one bond to an organic moiety.

Haloalkyl refers to a linear, cyclic or branched saturated alkyl group such as defined above in which at least one of the hydrogens has been replaced by a halide selected from the group of F, Cl, Br, I or mixture of these if more than one halo moiety is present. Fluoroalkyls are a specific subgroup of these moieties.

Fluoroalkyl refers to a linear, cyclic or branched saturated alkyl group as defined above in which the hydrogens have been replaced by fluorine either partially or fully (e.g., trifluoromethyl, pefluorocthyl, 2,2,2-trifluoroethyl, prefluoroisopropyl, perfluorocyclohexyl and the like). These fluoroalkyl moieties, if not perfluorinated, may be substituted or unsubstituted as described below.

Fluoroalkyloxy refers to a fluoroalkyl group as defined above on which is attached through an oxy (—O—) moiety it may be completed fluorinated (a.k.a. perfluorinated) or alternatively partially fluorinated (e.g., trifluoromethyoxy, perfluoroethyloxy, 2,2,2-trifluoroethoxy, perfluorocyclohexyloxy and the like). These fluoroalkyl moieties, if not pefluorinated may, be substituted or unsubstituted as described below.

Herein when referring to an alkyl, alkyloxy, fluoroalkyl, fluoroalkyloxy moieties with a possible range of carbon atoms which starts with C-1 such as for instance “C-1 to C-20 alkyl,” or “C-1 to C-20 fluoroalkyl,” as non-limiting examples, this range encompasses linear alkyls, alkyloxy, fluoroalkyl and fluoroalkyloxy starting with C-1 but only designated branched alkyls, branched alkyloxy, cycloalkyl, cycloalkyloxy, branched fluoroalkyl, and cyclic fluoroalkyl starting with C-3.

The term “alkylene” refers to hydrocarbon groups which can be a linear, branched or cyclic which has two or more attachment points (e.g., of two attachment points: methylene, ethylene, 1,2-isopropylene, a 1,4-cyclohexylene and the like; of three attachment points 1,1,1-subsituted methane, 1,1,2-subsituted ethane, 1,2,4-subsituted cyclohexane and the like). Here again, when designating a possible range of carbons, such as C-1 to C-20, as a non-limiting example, this range encompasses linear alkylenes starting with C-1 but only designates branched alkylenes, or cycloalkylene starting with C-3. These alkylene moieties may be substituted or unsubstituted as described below.

The term solid component as used herein refers to components which are not the solvent component g), namely in one embodiment components a), b), c), d), c) and f).

The terms “mono and “oligomeric” alkyleneoxyalkylene” encompasses both simple alkyleneoxyalkylene moiety such as ethyleneoxyethylene (—CH₂—CH₂—O—CH₂—CH₂—), propyleneoxypropylene (—CH₂—CH₂—CH₂—O—CH₂—CH₂—CH₂—), and the like, and also oligomeric materials such as di(ethyleneoxy)ethylene (—CH₂—CH₂——O—CH₂—CH₂—O—CH₂—CH₂—), di(propyleneoxy)propylene, (—CH₂—CH₂—CH₂—O—CH₂—CH₂—CH₂—O CH₂—CH₂—CH₂—), and the like.

The term “aryl” or “aromatic groups” refers to such groups which contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents, e.g., alkyl, alkoxy, acyl or aryl groups mentioned hereinabove.

The term “Novolak” (a.k.a. Novolac) if used herein without any other modifier of structure, refers to Novolak resins which are soluble in aqueous bases such as tetramethylammonium hydroxide and the like.

The term “PAG,” unless otherwise described, refers to a photoacid generator that can generate acid (a.k.a. photoacid) under deep UV or UV irradiation such as 200-300 nm, i-line, h-line, g-line and/or broadband irradiation. The acid may be a sulfonic acid, HCl, HBr, HAsF₆, and the like. It includes as non-limiting examples onium salt and other photosensitive compounds as known in the art that can photochemically generate c strong acids such as alkylsulfonic acid, arylsulfonic acid, HAsF₆″, HSbF₆″, HBF₄″, HPF₆″, CF₃SO₃H, HC(SO₂CF₃)₂″, HC(SO₂CF₃)₃, HN(SO₂CF₃)₂″, HB(C₆H₅)₄, HB(C₆F₅)₄, tetrakis(3,5-bis(trifluoromethyl)phenyl)borate acid, p-toluenesulfonic acid, HB(CF₃)₄ and cyclopentadiene penta-substituted with electron withdrawing groups such as cyclopenta-1,3-diene-1,2,3,4,5-pentacarbonitrile. Other photoacid generators include trihalomethyl compounds and also photosensitive derivative of trihalomethyl heterocyclic compounds which can generate a hydrogen halide such as HBr or HCl.

In one of its aspects, this invention is a positive working chemically amplified photosensitive composition comprising components a), b), c), d), c), f) and g) as follows:

### Component a)

Component a) is at least one random copolymer, having structure (A), wherein
the repeat unit of structure (I) ranges from about 17 mole % to about 70 mole %,
the repeat unit of structure (II) ranges from 0 to about 70 mole %,
the repeat unit of structure (III) ranges from 0 to about 70 mole %,
the sum of the repeat unit of structures (II) and (III) ranges from about 30 mole % to about 70 mole %,
the repeat unit of structure (IV) ranges from about 0 mole % to about 35 mole %, wherein the sum of the mole % of the repeat units of structure (I), (II), (III), and (IV) either does not exceed 100 mole % or is equal to 100 mole %, if other types of repeat units are not present, Ri₁, Ri₁₄, Ri₂, and Ri₁₃ are individually selected from H or a C-1 to C-4 alkyl, Ri₃, Ri₄, Ri₅, Ri₆, Ri₇, Ri₈, Ri₉, Ri₁₀, Ri₁₁, and Ri₁₂, are individually selected from H, a C-1 to C-8 alkyl, a C-1 to C-4 alkoxy, a phenyl, a substituted phenyl, and mixtures thereof, Li₁ is a C-2 to C-6 alkylene moiety, ni, mi, oi and pi are respectively the number of repeat units of structure (I), (II), (III) and (IV), and further wherein, the copolymer of structure (A) has a minimum dissolution rate of 500 Å/sec in 0.26 N tetramethylammonium hydroxide at 23° C., and does not comprise any repeat units which have acid cleavable groups;

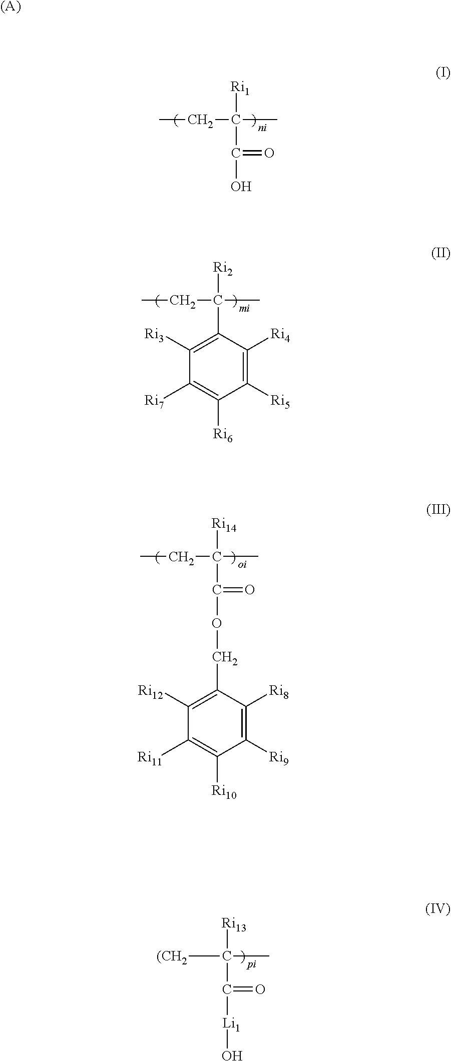

### Component b)

Component b) is at least one acrylic copolymer component of structure (B) comprising repeat units selected from ones having structure (1), (2), (3), (4), (5), (6), and (7): wherein
R₁, R₂, R₃, R₄, R₅, R₆, and R₇ are individually selected from either H, F, a C-1 to C-4 perfluoroalkyl, or a C-1 to C-4 alkyl,
R₈ and R₉ are individually selected from H, a C-1 to C-4 alkyl, a C-1 to C-4 alkyloxy alkyl, and a halogen,
R₁₀ is selected from the group consisting of a C-1 to C-8 primary alkyl, a C-3 to C-8 secondary alkyl, a C-3 to C-8 cyclic secondary alkyl, and a C-7 to C-14 secondary alicyclic alkyl,
R₁₁ is a C-2 to C-8 (hydroxy)alkylene moiety,
R₁₂ is a tertiary alkyl acid cleavable group, and
R₁₃ is a C-3 to C-12, (alkyloxy)alkylene moiety; and further
these repeat units in total constitute 100 mole % of the repeat units in said functionalized acrylic copolymer, where,
the repeat unit of structure (1) ranges from about 0 mole % to about 20 mole % of the acrylic copolymer,
the repeat unit of structure (2) ranges from about 0 mole % to about 20 mole % of the acrylic copolymer,
wherein the repeat unit of structure (3) ranges from about 5 mole % to about 55 mole % of the acrylic copolymer,
wherein the repeat unit of structure (4) ranges from about 0 mole % to about 30 mole % of the acrylic copolymer,
the repeat unit of structure (5) ranges from about 15 mole % to about 55 mole % of the acrylic copolymer,
the repeat unit of structure (6) ranges from about 18 mole % to about 40 mole % of the acrylic copolymer
the repeat unit of structure (7) ranges from about 0 mole % to about 40 mole % of the acrylic copolymer

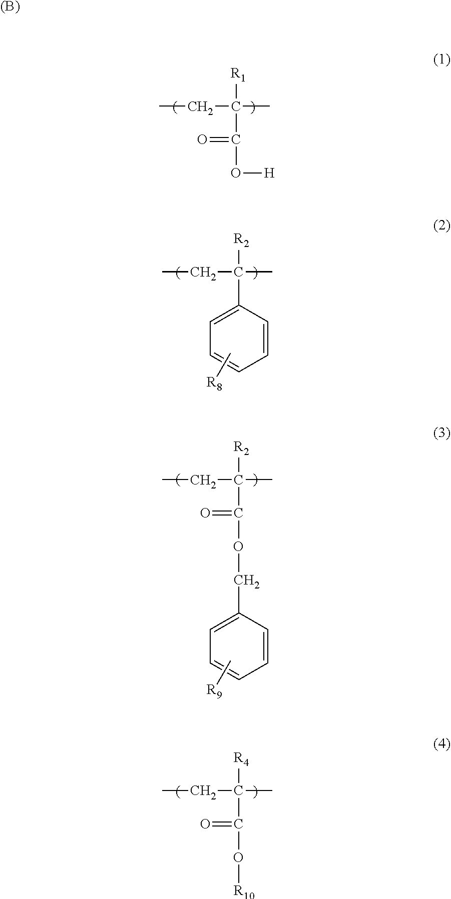

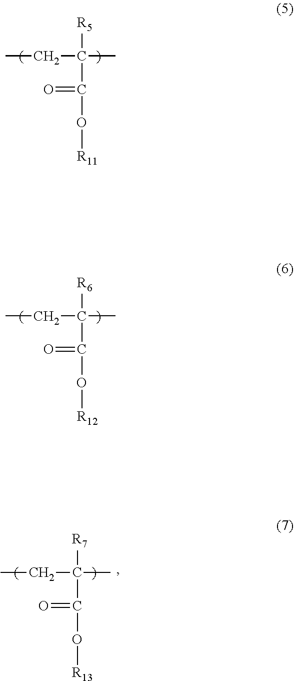

### Component c)

Component c) is at least one Novolak polymer.

### Component d)

Component d) is at least one photoacid generator (PAG).

### Component e)

Component e) is at least one base additive.

### Component f)

Component f) is at least one heterocyclic thiol compound.

### Component g)

Component g) is an organic spin casting solvent.

A more detailed account of specific embodiment of these components is as follow:

### Component a)

One aspect of this inventive composition is where component a) is a copolymer consisting of repeat units of structure (I) and (II). Another aspect of this embodiment is where component a) is a copolymer consisting of repeat units of structure (I), and (III).

Another aspect of this inventive composition is where component a) is copolymer consisting of the repeat units of structure (I), (II), and (III).

Another aspect of this inventive composition is where component a) is a copolymer consisting of repeat units of structure (I), (II) and (IV).

Another aspect of this embodiment is where component a) is a copolymer consisting of repeat units of structure (I), (III) and (IV).

Another aspect of this inventive composition is where component a) is a copolymer consisting of the repeat units of structure (I), (II), (III) and (IV).

Another aspect of this inventive composition is where component a), as described herein, is one where the repeat units of structure (I) ranges from about 17 mole % to about 65 mole %. In another aspect of this embodiment, it ranges from about 20 mole % to about 65 mole %. In one aspect of this embodiment Ri₁ is H. In another aspect Ri₁ is a C-1 to C-4 alkyl. In yet another aspect Ri₁ is methyl.

Another aspect of this inventive composition is where component a), as described herein, is one where the repeat units of structure (II), is present. In one aspect of this embodiment Ri₂ is H. In another aspect of this embodiment Ri₂ is a C-1 to C-4 alkyl. In still another aspect Ri₂ is a methyl.

Another aspect of this inventive composition is where component a), as described herein, is one where the repeat units of structure (III), is present. In one aspect of this embodiment Ri₁₄ is H. In another aspect of this embodiment Ri₁₄ is a C-1 to C-4 alkyl. In still another aspect Ri₁₄ is a methyl.

Another aspect of this inventive composition is where component a), as described herein, is one where the repeat units of structure (IV), is present. In one aspect of this embodiment Ri₁₃ is H. In another aspect of this embodiment Ri₁₃ is a C-1 to C-4 alkyl. In still another aspect Ri₁₃ is a methyl.

Another aspect of this inventive composition is where component a), as described herein, is one where component a) has structure (A-1).

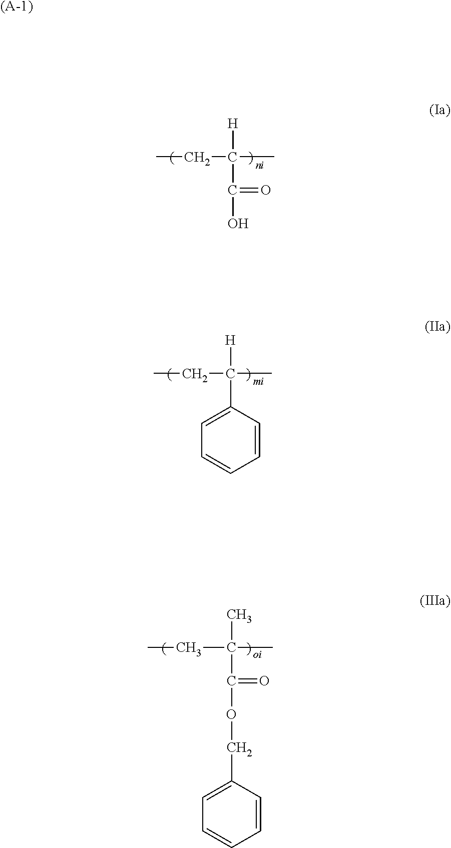

Another aspect of this inventive composition is where component a), as described herein, is one where component a) has structure (A-2). In one aspect of this embodiment the repeat unit of structure (Ia) ranges from about 20 mole % to about 70 mole %. In another aspect of this embodiment the repeat unit of structure (Ia) ranges from about 30 mole %, to about 70 mole %. In yet another aspect of this embodiment said repeat unit of structure (Ia) ranges from about 40 mole % to about 70 mole %. In still another aspect said repeat unit of structure (Ia) ranges from about 50 mole % to about 70 mole %. In yet another aspect said repeat unit of structure (Ia) ranges from about 60 mole % to about 70 mole %. In one aspect of this embodiment said repeat unit of structure (Ia) is about 50 mole %. In another aspect said repeat unit of structure (Ia) is about 60 mole %.

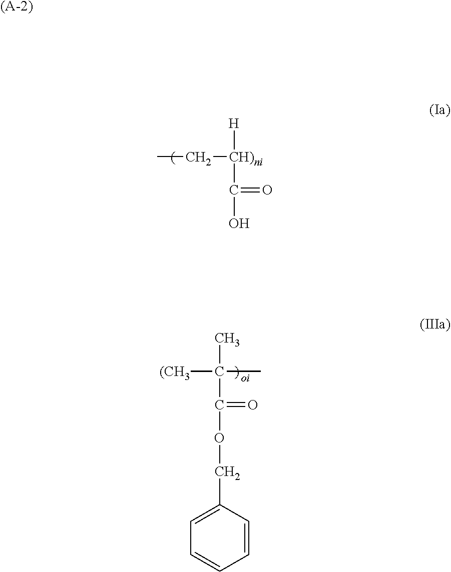

Another aspect of this inventive composition is where component a), as described herein, is one where component a) has structure (A-3). In one aspect of this embodiment the repeat unit of structure (Ia) ranges from about 20 mole % to about 70 mole %. In another aspect of this embodiment the repeat unit of structure (Ia) ranges from about 30 mole %, to about 70 mole %. In yet another aspect of this embodiment said repeat unit of structure (Ia) ranges from about 40 mole % to about 70 mole %. In still another aspect said repeat unit of structure (Ia) ranges from about 50 mole % to about 70 mole %. In yet another aspect said repeat unit of structure (Ia) ranges from about 60 mole % to about 70 mole %. In one aspect of this embodiment said repeat unit of structure (Ia) is about 50 mole %. In another aspect said repeat unit of structure (Ia) is about 60 mole %.

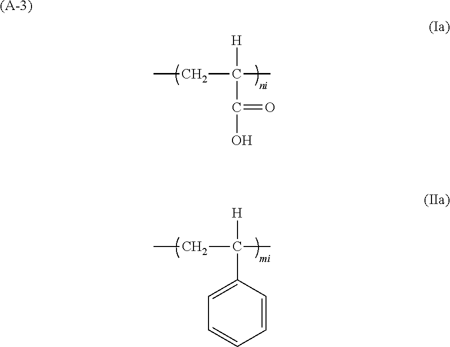

Another aspect of this inventive composition is where component a), as described herein, is one where component a) has structure (A-4). In another aspect of this embodiment the repeat unit of structure (Ia) ranges from about 17 mole %, to about 70 mole % (preferably to about 60 mole %), and the sum of the repeat unit of structure (IIa) and (IIIa) ranges from about 40 mole % to about 60 mole %. In yet another aspect of this embodiment said repeat unit of structure (Ia) ranges from about 17 mole % to about 60 mole % (preferably to about 55 mole %) and the sum of the repeat unit of structure (IIa) and (IIIa) ranges from about 45 mole % to about 65 mole %. In still another aspect said repeat unit of structure (Ia) ranges from about 17 mole % to about 50 mole %, and the sum of the repeat unit of structure (IIa) and (IIIa) ranges from about 45 mole % to about 65 mole %. In yet another aspect said repeat unit of structure (Ia) ranges from about 17 mole % to about 40 mole % and the sum of the repeat unit of structure (IIa) and (IIIa) ranges from about 45 mole % to about 65 mole %. In yet another aspect said repeat unit of structure (Ia) ranges from about 17 mole % to about 30 mole % and the sum of the repeat unit of structure (IIa) and (IIIa) ranges from about 45 mole % to about 55 mole %. In yet another aspect said repeat unit of structure (Ia) ranges from about 17 mole % to about 30 mole % and the sum of the repeat unit of structure (IIa) and (IIIa) ranges from about 45 mole % to about 50 mole %. In yet another aspect said repeat unit of structure (Ia) ranges from about 17 mole % to about 25 mole % and the sum of the repeat unit of structure (IIa) and (IIIa) ranges from about 45 mole % to about 50 mole %. In one aspect of this embodiment said repeat unit of structure (Ia) is about 25 mole %, and the sum of said repeat units of structure (IIa) and (IIIa) is about 45 mole %. In one aspect of this embodiment (Ia) is about 25 mole %, (IIa) is about 10 mole %, (IIIa) is about 35 mole %, and (IVa) is about 30 mole %. Further, in all these embodiments having structure (A-4) the mole % values of the repeat units having structures (Ia), (IIa), (IIIa) and (IVa) are chosen in their ranges to have a mole % which adds up to be equal and not exceed 100 mol %.

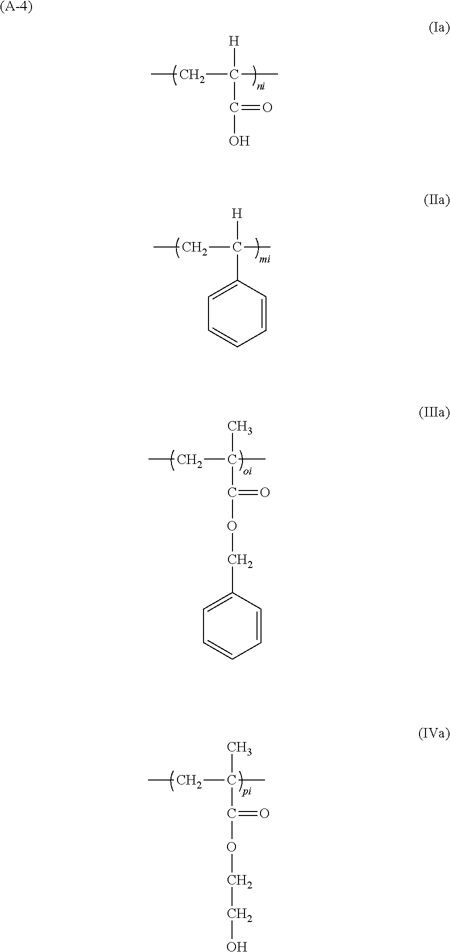

Another aspect of this inventive composition is where component a), as described herein, is one where component a) has structure (A-5). In another aspect of this embodiment the repeat unit of structure (Ia) ranges from about 17 mole %, to about 70 mole % (preferably to about 60 mole %), and the repeat unit of structure (IIIa) ranges from about 40 mole % to about 60 mole %. In yet another aspect of this embodiment said repeat unit of structure (Ia) ranges from about 17 mole % to about 60 mole % (preferably to about 55 mole %) and the repeat unit of structure (IIIa) ranges from about 45 mole % to about 65 mole %. In still another aspect said repeat unit of structure (Ia) ranges from about 17 mole % to about 50 mole %, and the repeat unit of structure (IIIa) ranges from about 45 mole % to about 65 mole %. In yet another aspect said repeat unit of structure (Ia) ranges from about 17 mole % to about 40 mole % and the repeat unit of structure (IIIa) ranges from about 45 mole % to about 65 mole %. In yet another aspect said repeat unit of structure (Ia) ranges from about 17 mole % to about 30 mole % and the repeat unit of structure (IIIa) ranges from about 45 mole % to about 55 mole %. In yet another aspect said repeat unit of structure (Ia) ranges from about 17 mole % to about 30 mole % and the repeat unit of structure (IIIa) ranges from about 45 mole % to about 50 mole %. In yet another aspect said repeat unit of structure (Ia) ranges from about 17 mole % to about 25 mole % and the repeat unit of structure (IIIa) ranges from about 45 mole % to about 50 mole %. In one aspect of this embodiment said repeat unit of structure (Ia) is about 20 mole %, and the repeat unit of structure (IIIa) is about 50 mole %. In one aspect of this embodiment (Ia) is about 20 mole %, (IIIa) is about 50 mole %, and (IVa) is about 30 mole %. Further, in all these embodiments having structure (A-5) the mole % values of the repeat units having structures (Ia), (IIIa) and (IVa) are chosen in their ranges to have a mole % which adds up to be equal and not exceed 100 mol %.

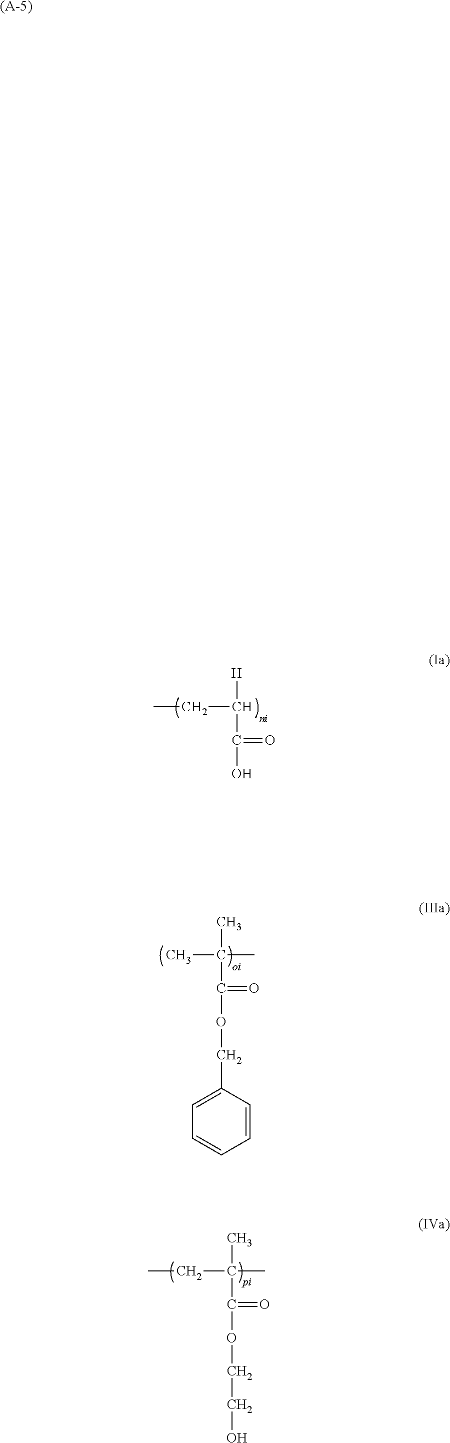

Another aspect of this inventive composition is where component a), as described herein, is one where component a) has structure (A-6). In another aspect of this embodiment the repeat unit of structure (Ia) ranges from about 17 mole %, to about 70 mole % (preferably to about 60 mole %), and the sum of the repeat unit of structure (IIa) and (IIIa) ranges from about 40 mole % to about 60 mole %. In yet another aspect of this embodiment said repeat unit of structure (Ia) ranges from about 17 mole % to about 60 mole % (preferably to about 55 mole %) and the sum of the repeat unit of structure (IIa) and (IIIa) ranges from about 45 mole % to about 65 mole %. In still another aspect said repeat unit of structure (Ia) ranges from about 17 mole % to about 50 mole %, and the sum of the repeat unit of structure (IIa) and (IIIa) ranges from about 45 mole % to about 65 mole %. In yet another aspect said repeat unit of structure (Ia) ranges from about 17 mole % to about 40 mole % and the sum of the repeat unit of structure (IIa) and (IIIa) ranges from about 45 mole % to about 65 mole %. In yet another aspect said repeat unit of structure (Ia) ranges from about 17 mole % to about 30 mole % and the sum of the repeat unit of structure (IIa) and (IIIa) ranges from about 45 mole % to about 55 mole %. In yet another aspect said repeat unit of structure (Ia) ranges from about 17 mole % to about 30 mole % and the sum of the repeat unit of structure (IIa) and (IIIa) ranges from about 45 mole % to about 50 mole %. In yet another aspect said repeat unit of structure (Ia) ranges from about 17 mole % to about 25 mole % and the sum of the repeat unit of structure (IIa) and (IIIa) ranges from about 45 mole % to about 50 mole %. In one aspect of this embodiment said repeat unit of structure (Ia) is about 25 mole %, and the sum of said repeat units of structure (IIa) and (IIIa) is about 45 mole %. In one aspect of this embodiment structure (Ia) is about 25 mole %, structure (IIa) is about 10 mole %, (IIIa) is about 35 mole %, and structure (IVb) is about 30 mole %. Further, in all these embodiments having structure (A-5) the mole % values of the repeat units having structures (Ia), (IIIa) and (IVa) are chosen in their ranges to have a mole % which adds up to be equal and not exceed 100 mol %.

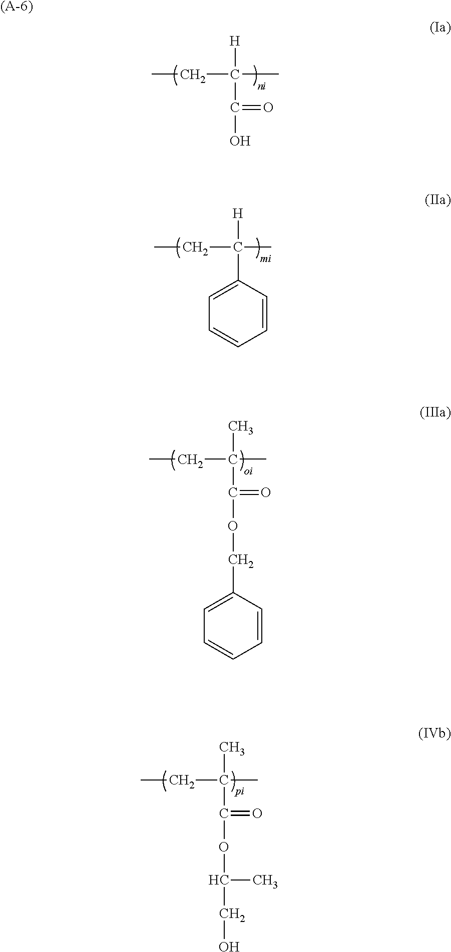

Another aspect of this inventive composition is where component a), as described herein, is one where component a) has structure (A-7). In another aspect of this embodiment the repeat unit of structure (Ia) ranges from about 17 mole %, to about 70 mole % (preferably to about 60 mole %), and the repeat unit of structure (IIIa) ranges from about 40 mole % to about 60 mole %. In yet another aspect of this embodiment said repeat unit of structure (Ia) ranges from about 17 mole % to about 60 mole % (preferably to about 55 mole %) and the repeat unit of structure (IIIa) ranges from about 45 mole % to about 65 mole %. In still another aspect said repeat unit of structure (Ia) ranges from about 17 mole % to about 50 mole %, and the repeat unit of structure (IIIa) ranges from about 45 mole % to about 65 mole %. In yet another aspect said repeat unit of structure (Ia) ranges from about 17 mole % to about 40 mole % and the repeat unit of structure (IIIa) ranges from about 45 mole % to about 65 mole %. In yet another aspect said repeat unit of structure (Ia) ranges from about 17 mole % to about 30 mole % and the repeat unit of structure (IIIa) ranges from about 45 mole % to about 55 mole %. In yet another aspect said repeat unit of structure (Ia) ranges from about 17 mole % to about 30 mole % and the repeat unit of structure (IIIa) ranges from about 45 mole % to about 50 mole %. In yet another aspect said repeat unit of structure (Ia) ranges from about 17 mole % to about 25 mole % and the repeat unit of structure (IIIa) ranges from about 45 mole % to about 50 mole %. In one aspect of this embodiment said repeat unit of structure (Ia) is about 20 mole %, and the repeat units of structure (IIIa) is about 50 mole %. In one aspect of this embodiment structure (Ia) is about 20 mole %, structure (IIIa) is about 50 mole %, and structure (IVb) is about 30 mole % Further, in all these embodiments having structure (A-5) the mole % values of the repeat units having structures (Ia), (IIIa) and (IVa) are chosen in their ranges to have a mole % which adds up to be equal and not exceed 100 mol %.

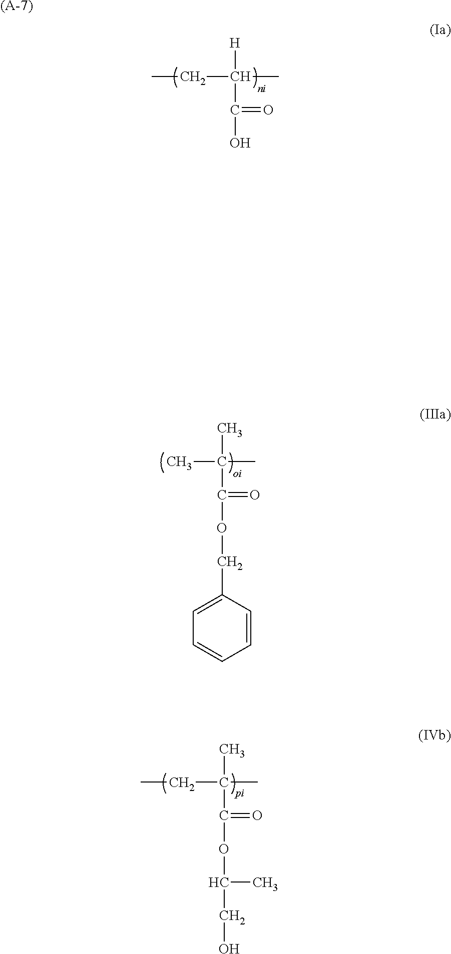

Another aspect of this inventive composition is where component a), as described herein, is one where component a) has structure (A-8). In another aspect of this embodiment the repeat unit of structure (Ia) ranges from about 17 mole %, to about 70 mole % (preferably to about 60 mole %), and the repeat unit of structure (IIa) ranges from about 40 mole % to about 60 mole %. In yet another aspect of this embodiment said repeat unit of structure (Ia) ranges from about 17 mole % to about 60 mole % (preferably to about 55 mole %) and the repeat unit of structure (IIa) ranges from about 45 mole % to about 65 mole %. In still another aspect said repeat unit of structure (Ia) ranges from about 17 mole % to about 50 mole %, and the repeat unit of structure (IIa) ranges from about 45 mole % to about 65 mole %. In yet another aspect said repeat unit of structure (Ia) ranges from about 17 mole % to about 40 mole % and the repeat unit of structure (IIa) ranges from about 45 mole % to about 65 mole %. In yet another aspect said repeat unit of structure (Ia) ranges from about 17 mole % to about 30 mole % and the repeat unit of structure (IIa) ranges from about 45 mole % to about 55 mole %. In yet another aspect said repeat unit of structure (Ia) ranges from about 17 mole % to about 30 mole % and the repeat unit of structure (IIa) ranges from about 45 mole % to about 50 mole %. In yet another aspect said repeat unit of structure (Ia) ranges from about 17 mole % to about 25 mole % and the repeat unit of structure (IIa) ranges from about 45 mole % to about 50 mole %. In one aspect of this embodiment said repeat unit of structure (Ia) is about 20 mole %, and the repeat units of structure (IIa) is about 45 mole %. Further, in all these embodiments having structure (A-5) the mole % values of the repeat units having structures (Ia), (IIla) and (IVa) are chosen in their ranges to have a mole % which adds up to be equal and not exceed 100 mol %.

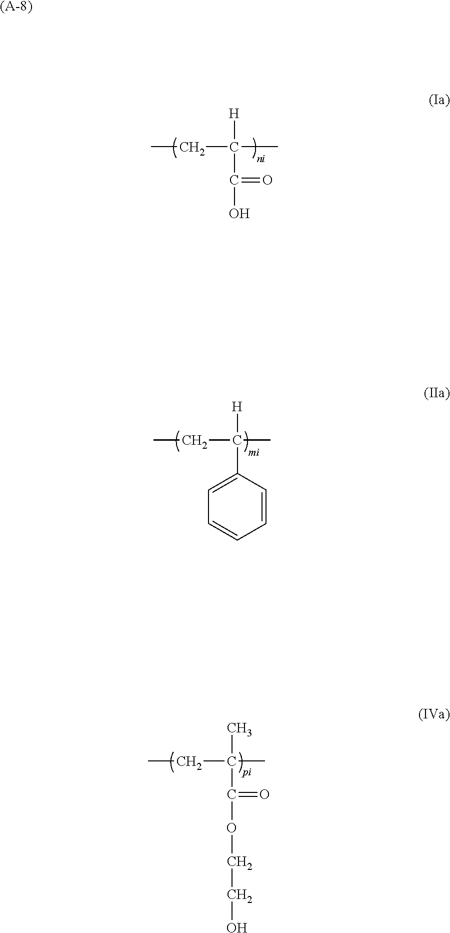

Another aspect of this inventive composition is where component a), as described herein, is one where component a) has structure (A-9). In another aspect of this embodiment the repeat unit of structure (Ia) ranges from about 17 mole %, to about 70 mole % (preferably to about 60 mole %), and the repeat unit of structure (IIa) ranges from about 40 mole % to about 60 mole %. In yet another aspect of this embodiment said repeat unit of structure (Ia) ranges from about 17 mole % to about 60 mole % (preferably to about 55 mole %), and the repeat unit of structure (IIa) ranges from about 45 mole % to about 65 mole %. In still another aspect said repeat unit of structure (Ia) ranges from about 17 mole % to about 50 mole %, and the repeat unit of structure (IIa) ranges from about 45 mole % to about 65 mole %. In yet another aspect said repeat unit of structure (Ia) ranges from about 17 mole % to about 40 mole % and the repeat unit of structure (IIa) ranges from about 45 mole % to about 65 mole %. In yet another aspect said repeat unit of structure (Ia) ranges from about 17 mole % to about 30 mole % and the repeat unit of structure (IIa) ranges from about 45 mole % to about 55 mole %. In yet another aspect said repeat unit of structure (Ia) ranges from about 17 mole % to about 30 mole % and the repeat unit of structure (IIa) ranges from about 45 mole % to about 50 mole %. In yet another aspect said repeat unit of structure (Ia) ranges from about 17 mole % to about 25 mole % and the repeat unit of structure (IIa) ranges from about 45 mole % to about 50 mole %. In one aspect of this embodiment said repeat unit of structure (Ia) is about 20 mole %, and the repeat units of structure (IIa) is about 45 mole %. Further, in all these embodiments having structure (A-5) the mole % values of the repeat units having structures (Ia), (IIIa) and (IVa) are chosen in their ranges to have a mole % which adds up to be equal and not exceed 100 mol %.

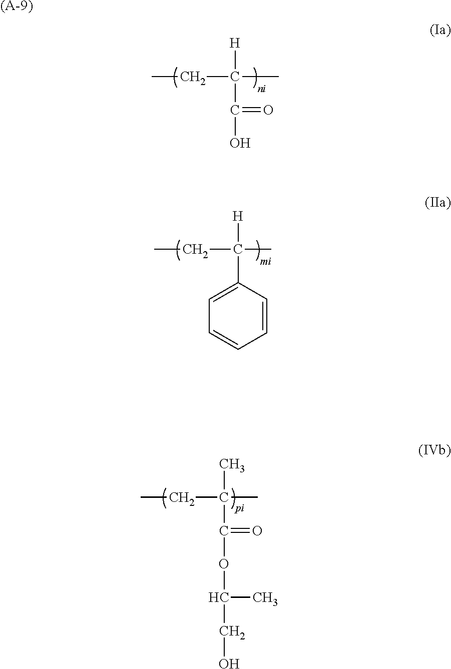

Another aspect of this inventive composition is where component a), as described herein, ranges from about 10 wt. % to about 25 wt. % of total solid components. In another aspect of this embodiment, it ranges from about 15 wt. % to about 22 wt. % of total solid components. In yet another aspect it ranges from about 17 wt. % to about 22 wt. % of total solid components. In yet another aspect it ranges from about 18 wt. % to about 21 wt. % of total solid components. In yet another aspect if ranges from about 19 wt. % to about 21 wt. %. In still another embodiment it is about 20 wt. %.

Another aspect of this inventive composition is where component a), as described herein, is a single one of these copolymers.

Another aspect of this inventive composition is where component a), as described herein, is one where component a) is a mixture of at least two different one of these copolymer.

### Component b)

Another aspect of this inventive composition is where component b), as described herein, ranges from about 20 wt. % to about 65 wt. % of total solids. In another aspect of this embodiment, it ranges from about 25 wt. % to about 60 wt. % of total solids. In another aspect of this embodiment, it ranges from about 30 wt. % to about 55 wt. % of total solids. In another aspect of this embodiment, it ranges from about 30 wt. % to about 50 wt. % of total solids. In another aspect of this embodiment, it ranges from about 30 wt. % to about 45 wt. % of total solids. In another aspect of this embodiment, it ranges from about 30 wt. % to about 40 wt. % of total solids. In another aspect of this embodiment, it ranges from about 32 wt. % to about 38 wt. % of total solids. In another aspect of this embodiment, it ranges from about 33 wt. % to about 37 wt. % of total solids. In another aspect of this embodiment, it ranges from about 34 wt. % to about 36 wt. % of total solids. In another aspect of this embodiment, it is about 35 wt. % of total solids.

Another aspect of this inventive composition is where component b), as described herein, is a single copolymer of structure (B).

Another aspect of this inventive composition is where component b), as described herein, is at least two different copolymers of structure (B).

Another aspect of this inventive composition is where component b), as described herein, comprises at least one copolymer of structure (B) which comprises from about 5 mole % to about 20 mole % of the repeat unit of structure (1).

Another aspect of this inventive composition is where component b), as described herein, comprises at least one copolymer of structure (B) which comprises from about 5 mole % to about 20 mole % of the repeat unit of structure (7).

Another aspect of this inventive composition is where component b), as described herein, comprises at least one copolymer of structure (B) in which the repeat unit of structure (1) ranges from about 5 mole % to about 20 mole % and the repeat unit of structure (7) ranges from about 5 mole % to about 20 mole %.

Another aspect of this inventive composition is where component b), as described herein, comprises at least one copolymer of structure (B), where at least one said copolymer consists from about 5 mole % to about 10 mole % of the repeat unit of structure (1), from about 15 mole % to about 20 mole % of the repeat unit of structure (3), from about 25 mole % to about 35 mole % of the repeat unit of structure (5), and from about 40 mole % to about 50 mole % of the repeat unit of structure (6).

Another aspect of this inventive composition is where component b), as described herein, comprises at least one copolymer of structure (B), where at least one said copolymer consists of from about 5 mole % to about 15 mole % of the repeat unit of structure (1), from about 15 mole % to about 25 mole % of the repeat unit of structure (3), from about 35 mole % to about 45 mole % of the repeat unit of structure (5), and from about 25 mole % to about 35 mole % of the repeat unit of structure (6).

Another aspect of this inventive composition is where component b), as described herein, comprises at least one copolymer of structure (B), where at least one said copolymer consists from about 5 mole % to about 10 mole % of the repeat unit of structure (1), from about 15 mole % to about 25 mole % of the repeat unit of structure (3), from about 45 mole % to about 55 mole % of the repeat unit of structure (5), from about 15 mole % to about 25 mole % of the repeat unit of structure (6).

Another aspect of this inventive composition is where component b), as described herein, comprises at least one copolymer of structure (B), where at least one said copolymer consists from about 5 mole % to about 10 mole % of the repeat unit of structure (1), from about 12 mole % to about 22 mole % of the repeat unit of structure (3), from about 20 mole % to about 35 mole % of the repeat unit of structure (5), about 25 mole % to about 40 mole % of the repeat unit of structure (6) and from about 5 mole % to about 15 mole % of the repeat unit of structure (7).

Another aspect of this inventive composition is where component b), as described herein, comprises at least one copolymer of structure (B), where at least one said copolymer consists from about 12 mole % to about 22 mole % of the repeat unit of structure (3), from about 30 mole % to about 40 mole % of the repeat unit of structure (5), from about 25 mole % to about 40 mole % of the repeat unit of structure (6), and from about 5 mole % to about 15 mole % of the repeat unit of structure (7).

Another aspect of this inventive composition is where component b), as described herein, comprises at least one copolymer of structure (B), where at least one said copolymer consists from about 5 mole % to about 8 mole % of the repeat unit of structure (1), from about 10 mole % to about 17 mole % of the repeat unit of structure (3), from about 30 mole % to about 40 mole % of the repeat unit of structure (5), from about 25 mole % to about 40 mole % of the repeat unit of structure (6), and from about 5 mole % to about 15 mole % of the repeat unit of structure (7).

Another aspect of this inventive composition is where component b), as described herein, comprises at least one copolymer of structure (B), where at least one said copolymer consists from about 5 mole % to about 7.5 mole % of the repeat unit of structure (1), from about 10 mole % to about 17 mole % of the repeat unit of structure (3), from about 30 mole % to about 40 mole % of the repeat unit of structure (5), from about 25 mole % to about 40 mole % of the repeat unit of structure (6), and from about 5 mole % to about 15 mole % of the repeat unit of structure (7).

Another aspect of this inventive composition is where component b), as described herein, comprises at least one copolymer of structure (B), where at least one said copolymer consists from about 5 mole % to about 15 mole % of the repeat unit of structure (1), from about 5 mole % to about 15 mole % of the repeat unit of structure (3), from about 30 mole % to about 40 mole % of the repeat unit of structure (5), from about 25 mole % to about 40 mole % of the repeat unit of structure (6), and from about 5 mole % to about 15 mole % of the repeat unit of structure (7).

Another aspect of this inventive composition is where component b), as described herein, comprises at least one copolymer of structure (B), where at least one said copolymer consists from about 5 mole % to about 15 mole % of the repeat unit of structure (1), from about 20 mole % to about 35 mole % of the repeat unit of structure (3), from about 30 mole % to about 40 mole % of the repeat unit of structure (5), from about 15 mole % to about 25 mole % of the repeat unit of structure (6), and from about 5 mole % to about 15 mole % of the repeat unit of structure (7).

Another aspect of this inventive composition is where component b), as described herein, comprises at least one copolymer of structure (B), where at least one said copolymer consists from about 5 mole % to about 15 mole % of the repeat unit of structure (1), from about 20 mole % to about 30 mole % of the repeat unit of structure (3), from about 35 mole % to about 45 mole % of the repeat unit of structure (5), from about 15 mole % to about 25 mole % of the repeat unit of structure (6), and from about 5 mole % to about 15 mole % of the repeat unit of structure (7).

Another aspect of this inventive composition is where component b), as described herein, comprises at least one copolymer of structure (B), where at least one said copolymer consists from about 7 mole % to about 18 mole % of the repeat unit of structure (1), from about 15 mole % to about 25 mole % of the repeat unit of structure (3), from about 25 mole % to about 35 mole % of the repeat unit of structure (5), from about 15 mole % to about 25 mole % of the repeat unit of structure (6), and from about 5 mole % to about 15 mole % of the repeat unit of structure (7). In another aspect it comprises only one copolymer of structure (B).

Another aspect of this inventive composition is where component b), as described herein, comprises at least one copolymer of structure (B), where at least one said copolymer consists from about 7 mole % to about 15 mole % of the repeat unit of structure (1), from about 25 mole % to about 35 mole % of the repeat unit of structure (3), from about 25 mole % to about 35 mole % of the repeat unit of structure (5), from about 25 mole % to about 35 mole % of the repeat unit of structure (6).

Another aspect of this inventive composition is where component b), as described herein, comprises at least one copolymer of structure (B), where at least one said copolymer consists from about 7 mole % to about 15 mole % of the repeat unit of structure (1), from about 27 mole % to about 45 mole % of the repeat unit of structure (3), from about 30 mole % to about 40 mole % of the repeat unit of structure (5), from about 15 mole % to about 25 mole % of the repeat unit of structure (6).

Another aspect of this inventive composition is where component b), as described herein, comprises at least one copolymer of structure (B), where at least one said copolymer consists from about 7 mole % to about 15 mole % of the repeat unit of structure (1), from about 15 mole % to about 25 mole % of the repeat unit of structure (3), from about 35 mole % to about 45 mole % of the repeat unit of structure (5), from about 25 mole % to about 35 mole % of the repeat unit of structure (6).

Another aspect of this inventive composition is where component b), as described herein, comprises at least one copolymer of structure (B), where at least one said copolymer consists from about 7 mole % to about 15 mole % of the repeat unit of structure (1), from about 20 mole % to about 37 mole % of the repeat unit of structure (3), from about 30 mole % to about 45 mole % of the repeat unit of structure (5), from about 20 mole % to about 30 mole % of the repeat unit of structure (6).

Another aspect of this inventive composition is where component b), as described herein, comprises at least one copolymer of structure (B), where at least one said copolymer consists from about 7 mole % to about 15 mole % of the repeat unit of structure (1), from about 20 mole % to about 30 mole % of the repeat unit of structure (3), from about 30 mole % to about 45 mole % of the repeat unit of structure (5), from about 20 mole % to about 35 mole % of the repeat unit of structure (6).

Another aspect of this inventive composition is where component b), as described herein, comprises at least one copolymer of structure (B), where at least one said copolymer consists from about 10 mole % to about 20 mole % of the repeat unit of structure (1), from about 20 mole % to about 30 mole % of the repeat unit of structure (3), from about 30 mole % to about 45 mole % of the repeat unit of structure (5), from about 20 mole % to about 35 mole % of the repeat unit of structure (6).

Another aspect of this inventive composition is where component b), as described herein, comprises at least one copolymer of structure (B), where at least one said copolymer consists from about 15 mole % to about 20 mole % of the repeat unit of structure (1), from about 15 mole % to about 27 mole % of the repeat unit of structure (3), from about 30 mole % to about 45 mole % of the repeat unit of structure (5), from about 20 mole % to about 35 mole % of the repeat unit of structure (6).

Another aspect of this inventive composition is where component b), as described herein, comprises at least one copolymer of structure (B), where at least one said copolymer consists from about 12 mole % to about 20 mole % of the repeat unit of structure (1), from about 17 mole % to about 30 mole % of the repeat unit of structure (3), from about 30 mole % to about 45 mole % of the repeat unit of structure (5), from about 20 mole % to about 35 mole % of the repeat unit of structure (6).

Another aspect of this inventive composition is where component b), as described herein, comprises at least one copolymer of structure (B), where at least one said copolymer consists from about 12 mole % to about 20 mole % of the repeat unit of structure (1), from about 15 mole % to about 20 mole % of the repeat unit of structure (3), from about 30 mole % to about 45 mole % of the repeat unit of structure (5), from about 20 mole % to about 35 mole % of the repeat unit of structure (6).

Another aspect of this inventive composition is where component b), as described herein, comprises a second copolymer of structure (B), where at least one said copolymer consists about 5 mole % to about 15 mole % of the repeat unit of structure (1), from about 15 mole % to about 25 mole % of the repeat unit of structure (3), from about 35 mole % to about 45 mole % of the repeat unit of structure (5), and from about 25 mole % to about 35 mole % of the repeat unit of structure (6).

Another aspect of this inventive composition is where component b), as described herein, where component b) is only one type of copolymer of structure (B).

44 Another aspect of this inventive composition is where component b), as described herein, where component b) comprises a second different copolymer of structure (B).

Another aspect of this inventive composition, as described herein, is where in component b), the repeat unit of structure (1), if present, has either structures (1a) or (1b),

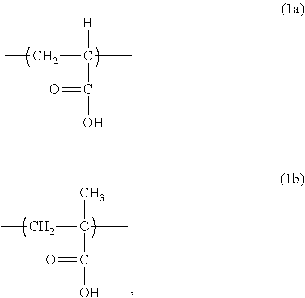

Another aspect of this inventive composition, as described herein, is where in component b), the repeat unit of structure (3) has either structures (3a) or (3b),

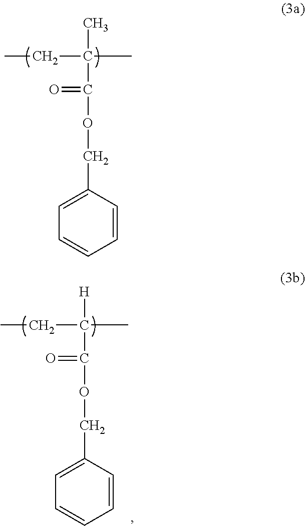

the repeat unit of structure (5) has either structures (5a) or (5b),

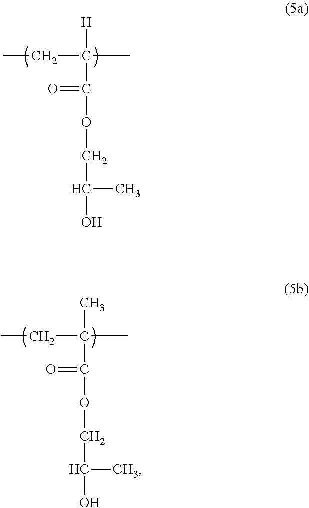

the repeat unit of structure (7), if present, has either structure (7a) or (7b),

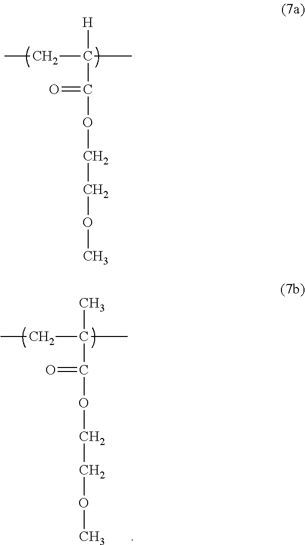

the repeat unit of structure (6), has either structures (6a), (6b), (6c) or (6d)

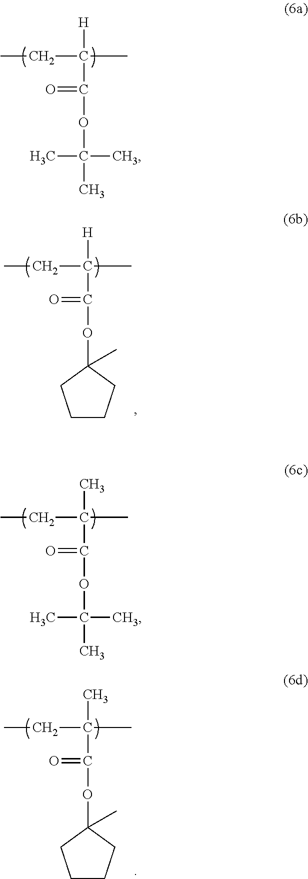

### Component c)

Another aspect of this inventive composition is where component c), said Novolak polymer, as described herein, ranges from about 20 wt. % to about 65 wt. % of total solids. In another aspect of this embodiment said Novolak polymer ranges from about 25 wt. % to about 60 wt. % of total solids. In another aspect of this embodiment said Novolak polymer ranges from about 30 wt. % to about 55 wt. % of total solids. In another aspect of this embodiment said Novolak polymer ranges from about 35 wt. % to about 60 wt. % of total solids. In another aspect of this embodiment said Novolak polymer ranges from about 35 wt. % to about 55 wt. % of total solids. In another aspect of this embodiment said Novolak polymer ranges from about 35 wt. % to about 50 wt. % of total solids. In another aspect of this embodiment said Novolak polymer ranges from about 30 wt. % to about 55 wt. % of total solids. In another aspect of this embodiment said Novolak polymer ranges from about 30 wt. % to about 50 wt. % of total solids. In another aspect of this embodiment said Novolak polymer ranges from about 35 wt. % to about 50 wt. % of total solids. In another aspect of this embodiment said Novolak polymer ranges from about 35 wt. % to about 50 wt. % of total solids. In another aspect of this embodiment said Novolak polymer ranges from about 38 wt. % to about 48 wt. % of total solids. In another aspect of this embodiment said Novolak polymer ranges from about 39 wt. % to about 47 wt. % of total solids. In another aspect of this embodiment said Novolak polymer ranges from about 40 wt. % to about 46 wt. % of total solids. In another aspect of this embodiment said Novolak polymer ranges from about 41 wt. % to about 45 wt. % of total solids. In another aspect of this embodiment said Novolak polymer ranges from about 42 wt. % to about 45 wt. % of total solids. In another aspect of this embodiment said Novolak polymer ranges from about 43 wt. % to about 45 wt. % of total solids. In another aspect of this embodiment said Novolak polymer is about 44 wt. % of total solids.

Another aspect of this inventive composition, as described herein, is where in component c), the Novolak-based resin component comprises repeat unit of structure (N) where Ra1, Ra2 and Ra3 are cach independently (i) a hydrogen, (ii) an unsubstituted C-1 to C-4 alkyl, (iii) a substituted C-1 to C-4 alkyl, (iv) an unsubstituted -X-Phenol group where X is —O—, —C(CH₃)₂—, —CH₂—, —C(═O)— or —SO₂— or (v) an substituted -X-Phenol group where X is —O—, —C(CH₃)₂—, —CH₂—, —C(═O)— or —SO₂—. In another aspect of this embodiment, Ra1 and Ra2 are cach hydrogen and Ra3 is an unsubstituted C-1 to C-4 alkyl. In yet another aspect of this embodiment, Ra1 and Ra2 are cach hydrogen and Ra3 is —CH₃. In still another aspect of this embodiment, the repeat unit (N) has the structure (NA). In another aspect of this embodiment, Novolak-based resin component further comprises one or more of repeat units of structure (NB) where (i) Ra1, Ra2 and Ra3 are cach independently a hydrogen, an unsubstituted C-1 to C-4 alkyl or a substituted C-1 to C-4 alkyl, (ii) X is —O—, —C(CH₃)₂—, —CH₂—, —C(═O)—, or —SO₂— and (iii) each Ra4 is independently a hydrogen, an unsubstituted C-1 to C-4 alkyl or a substituted C-1 to C-4 alkyl, in a specific aspect of this embodiment structure (NB) has the more specific structure (NC).

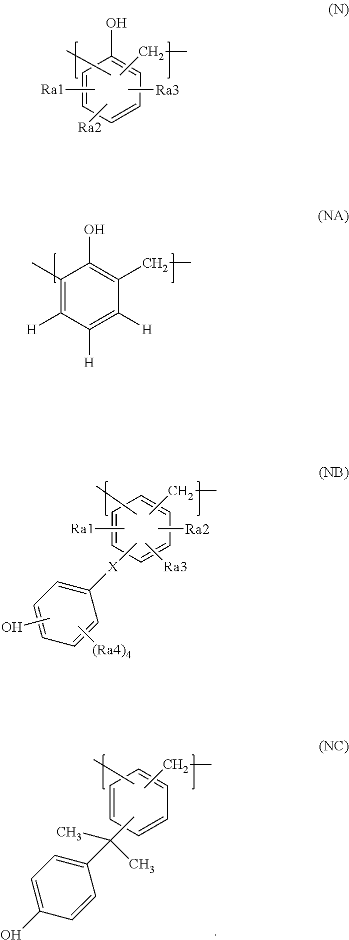

### Component d)

Another aspect of this inventive composition, as described herein, is where in component d), the photo acid generator (PAG) is any compound that can photo generate acid (a.k.a, photoacid) under deep UV or UV irradiation such as 200-300 nm, i-line, h-line, g-line and/or broadband irradiation. The acid may be a sulfonic acid, HC., HBr, HAsF₆, and the like. It includes as non-limiting examples onium salt and other photosensitive compounds as known in the art that can photochemically generate c strong acids such as alkylsulfonic acid, arylsulfonic acid, HASF₆, HSbF₆, HBF⁴, HPF₆, CF₃SO₃H, HC(SO₂CF3)₂, HC(SO₂CF₃)₃, HN(SO₂CF₃)₂, HB(C₆H₅)₄, HB(C₆F₅)₄, tetrakis(3,5-bis(trifluoromethyl)phenyl)borate acid, p-toluenesulfonic acid, HB(CF₃)₄ and cyclopentadiene penta-substituted with electron withdrawing groups such as cyclopenta-1,3-diene-1,2,3,4,5-pentacarbonitrile. Other photoacid generators include trihalomethyl compounds and photosensitive derivative of trihalomethyl heterocylic compounds which can generate a hydrogen halide such as HBr or HCl. In one aspect of this embodiment the PAG may be an aromatic imide N-oxysulfonate derivative of an organic sulfonic acid, an aromatic sulfonium salt of an organic sulfonic acid, a trihalotriazine derivative or a mixture thereof. In one aspect of this embodiment, it has structure (P) wherein R₁ₚ is a fluoroalkyl moiety and R₂ₚ is H, an alkyl, an oxyalkyl, a thioalkyl, or an aryl moiety. In another aspect of this embodiment, it has structure (PA) wherein R₃ₚ is a fluoroalkyl, an alkyl or an aryl moiety and R₄ₚ is H, an alkyl, an oxyalkyl, a thioalkyl, or an aryl moiety. Another aspect of this inventive composition. as described herein, is where component d), the photo acid generator (PAG) component comprises 1,3-dioxo-1H-benzo[de]isoquinolin-2(3H)-yl trifluoromethanesulfonate (NIT PAG).

Another aspect of this inventive composition is where component d), said phototoacid generator, as described herein, ranges from about 0.1 wt. % to about 2 wt. % of total solids. In another aspect of this embodiment said photoacid generator ranges from about 0.15 wt. % to about 1.8 wt. % of total solids. In another aspect of this embodiment said photoacid generator ranges from about 0.2 wt. % to about 1.6 wt. % of total solids. In another aspect of this embodiment said photoacid generator ranges from about 0.2 wt. % to about 1.5 wt. % of total solids. In another aspect of this embodiment said photoacid generator ranges from about 0.25 wt. % to about 1.4 wt. % of total solids. In another aspect of this embodiment said photoacid generator ranges from about 0.25 wt. % to about 1.3 wt. % of total solids. In another aspect of this embodiment said photoacid generator ranges from about 0.30 wt. % to about 1.2 wt. % of total solids. In another aspect of this embodiment said photoacid generator ranges from about 0.30 wt. % to about 1.1 wt. % of total solids. In another aspect of this embodiment said photoacid generator ranges from about 0.35 wt. % to about 1.0 wt. % of total solids. In another aspect of this embodiment said photoacid generator ranges from about 0.40 wt. % to about 0.8 wt. % of total solids. In another aspect of this embodiment said photoacid generator ranges from about 0.40 wt. % to about 0.9 wt. % of total solids.

In another aspect of this embodiment said photoacid generator ranges from about 0.40 wt. % to about 0.7 wt. % of total solids. In another aspect of this embodiment said photoacid generator ranges from about 0.40 wt. % to about 0.7 wt. % of total solids. In another aspect of this embodiment said photoacid generator ranges from about 0.40 wt. % to about 0.60 wt. % of total solids. In another aspect of this embodiment said photoacid generator ranges from about 0.45 wt. % to about 0.55 wt. % of total solids. In another aspect of this embodiment said photoacid generator ranges is about 0.5 wt. % of total solids.

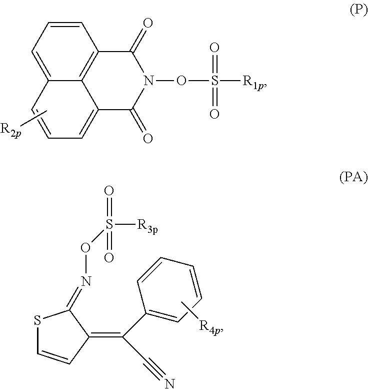

### Component e)

Another aspect of this inventive composition, as described herein, is component e), the base additive, where this base additive can include, but is not limited to a basic material or combination of materials such as an amine compound or a mixture of amine compounds having a boiling point above 100° C., at atmospheric pressure, and a pKₐ of at least 1. Such acid quenchers include, but are not limited to, amine compounds having structures (XIIa), (XIIb), (XIIc), (XIId), (XIIe), (XIIf), (XIIg), (XIIh), (XIIi) (XIIj), (XIIk) and (XIIl) or a mixture of compounds from this group; wherein R_{b1} is C-1 to C-20 saturated alkyl chain or a C-2 to C-20 unsaturated alkyl chain; R_{b2}, R_{b3}, R_{b4}, R_{b5}, R_{b6}, R_{b7}, R_{b8}, R_{b9}, R_{b10}, R_{b11}, R_{b12} and R_{b13}, are independently selected from the group of H, and a C-1 to C-20 alkyl.

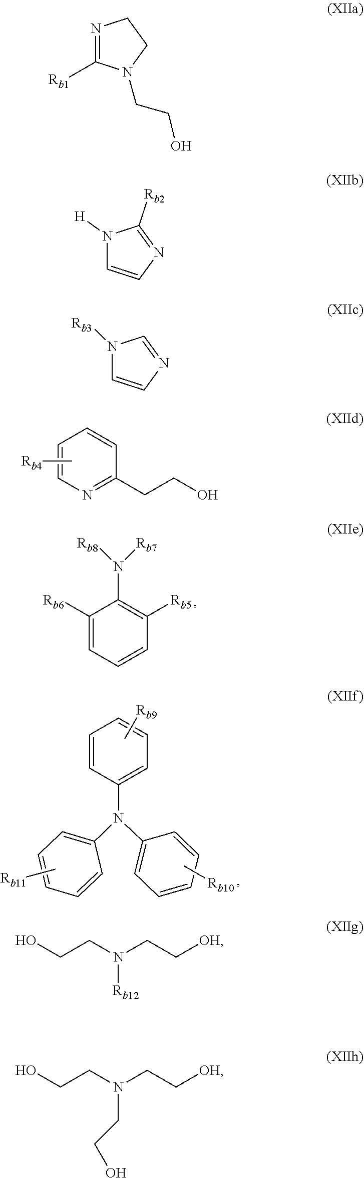

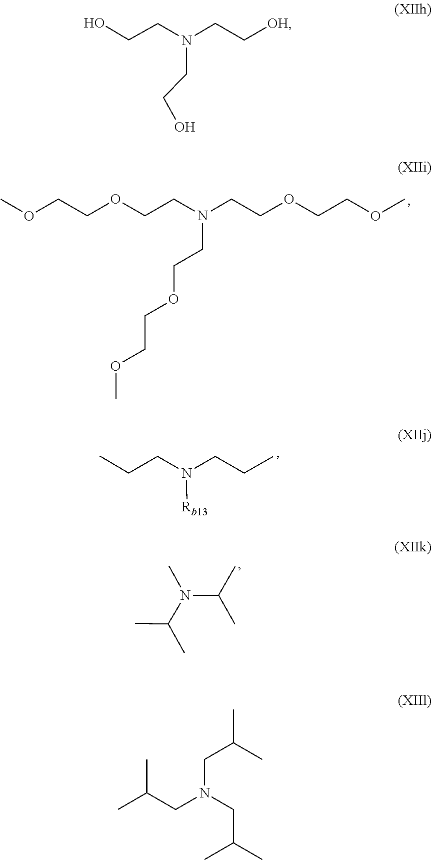

Component e) can also be chosen from, but is not limited to, a basic material or combination of materials which are tetraalkylammonium or trialkylammonium salts of a dicarboxylic acid or mixtures of these. Specific non limiting examples are mono(tetraalkyl ammonium) of dicarboxylic acid, di(tetraalkyl ammonium) salts of dicarboxylic acid, mono(trialkyl ammonium) of dicarboxylic acid, or di(trialkyl ammonium) salts of dicarboxylic acid. Non-limiting examples of suitable dicarboxylic acid for these salts are oxalic acid, maleic acid, malonic acid, fumaric acid, phthalic acid, and the like. Structure (XIIma) to (XIImd) gives a general structure for such materials wherein Rqa, Rqb, Rqc and Rqd are independently a C-4 to C-8 alkyl group, Rqe is a valence bond, an arylene moiety, a C-1 to C-4 alkylene moiety, an alkenyl moiety (—C(Rqf)═C(Rqg)—, wherein Rqf and Rqg are independently H or a C-1 to C-4 alkyl). Structure (XIIme) gives a specific example of such a material.

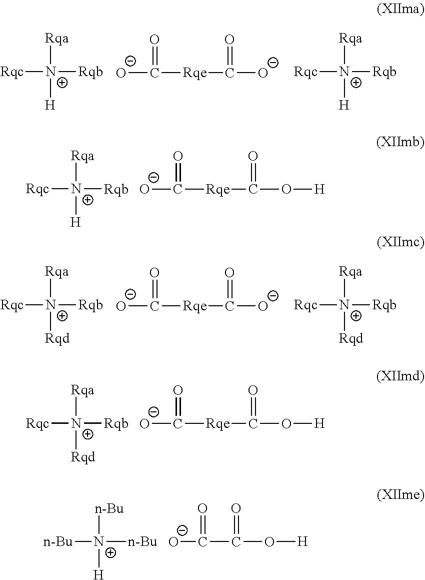

Another aspect of this inventive composition is where component e), said base additive, as described herein, ranges from about 0.0001 wt. % to about 0.010 wt. % of total solids. In another aspect of this embodiment said base additive ranges from about.0015 wt. % to about 0.0090 wt. % of total solids. In another aspect of this embodiment said base additive ranges 0.0020 wt. % to about 0.0085 wt. % of total solids. In another aspect of this embodiment said base additive ranges 0.0025 wt. % to about 0.0080 wt. % of total solids. In another aspect of this embodiment said base additive ranges 0.0030 wt. % to about 0.0075 wt. % of total solids. In another aspect of this embodiment said base additive ranges 0.0035 wt. % to about 0.0070 wt. % of total solids. In another aspect of this embodiment said base additive ranges 0.0040 wt. % to about 0.0060 wt. % of total solids. In another aspect of this embodiment said base additive ranges 0.0045 wt. % to about 0.0055 wt. % of total solids. In another aspect of this embodiment said base additive is about 0.0050 wt. % of total solids.

### Component f)

Another aspect of this inventive composition, as described herein, is component f), a heterocyclic thiol compound, chosen from the general formulas (H1), (H2) and (H3), in said structure (H1), Xt is selected from the group consisting of N(Rt₃), C(Rt₁)(Rt₂), O, S, Se, and Te; In said structure (H2), Y is selected from the group consisting of C(Rt₃) and N; in said structure (H3), Z is selected from the group consisting of C(Rt₃) and N; and Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms.

Structures (1t) to (19t), show specific examples of suitable heterocyclic thiol, which may be used in the inventive composition:

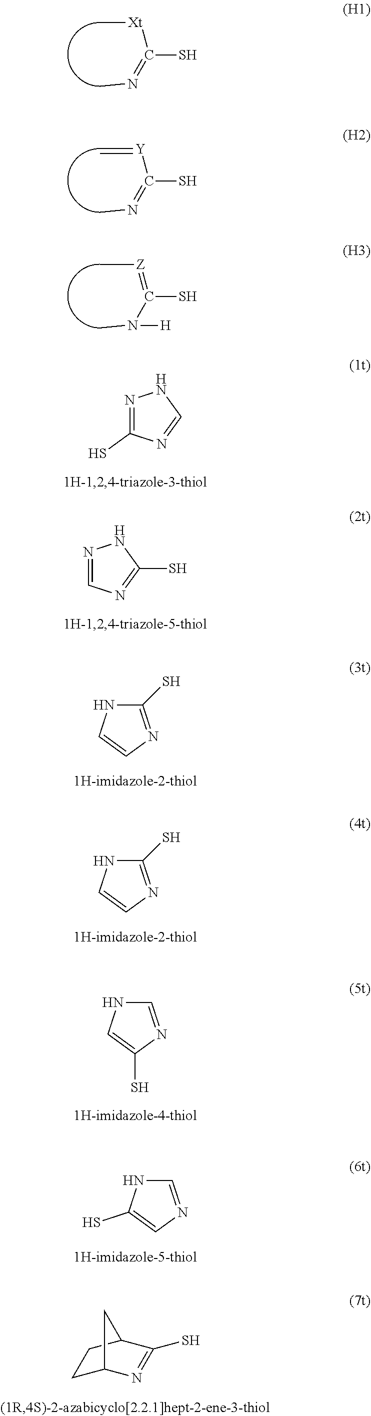

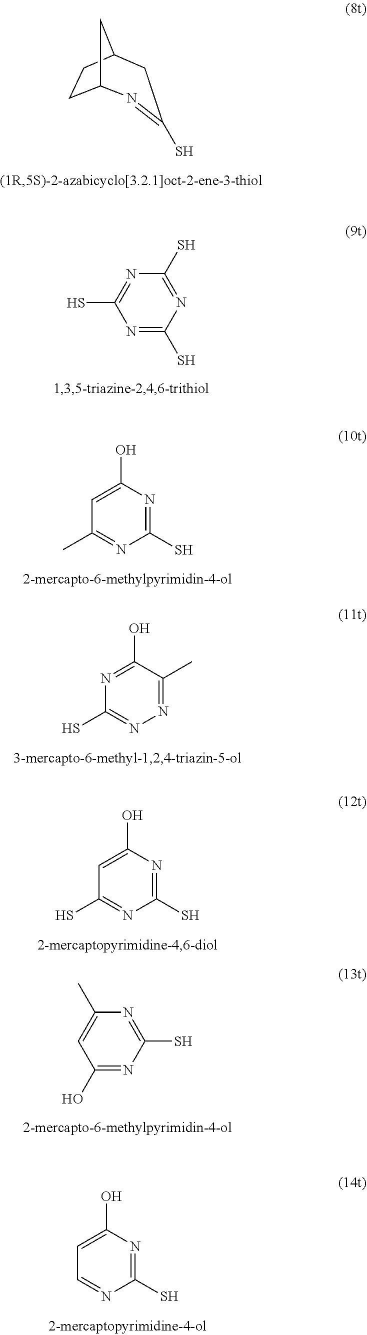

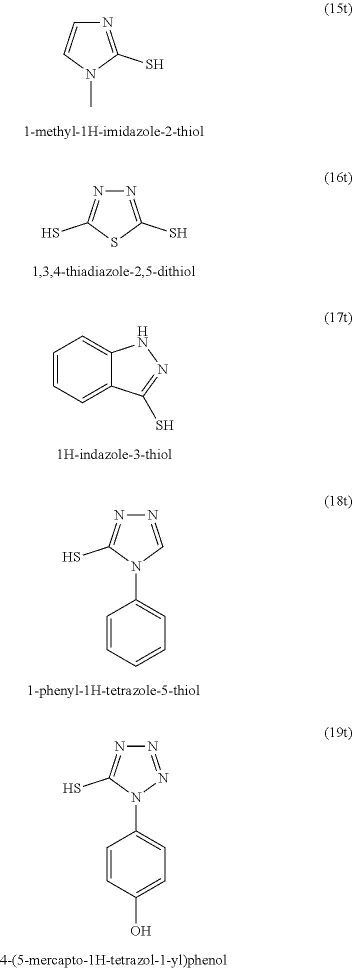

Another aspect of this inventive composition is where component f), this heterocyclic thiol compound, as described herein, ranges from about 0.01 wt. % to about 1.5 wt. % of total solids. In another aspect of this embodiment this heterocyclic thiol compound ranges from about 0.04 wt. % to about 1.2 wt. % of total solids. In another aspect of this embodiment this heterocyclic thiol compound ranges from about 0.08 wt. % to about 1.1 wt. % of total solids. In another aspect of this embodiment this heterocyclic this thiol compound ranges from about 0.09 wt. % to about 1.0 wt. % of total solids. In another aspect of this embodiment this heterocyclic thiol compound ranges from about 0.10 wt. % to about 0.9 wt. % of total solids. In another aspect of this embodiment this heterocyclic thiol compound ranges from about 0.15 wt. % to about 0.8 wt. % of total solids. In another aspect of this embodiment this heterocyclic thiol compound ranges from 0.20 wt. % to about 0.75 wt. % of total solids. In another aspect of this embodiment this heterocyclic thiol compound ranges from 0.25 wt. % to about 0.74 wt. % of total solids. In another aspect of this embodiment this heterocyclic thiol compound ranges from 0.30 wt. % to about 0.74 wt. % of total solids. In another aspect of this embodiment this heterocyclic thiol compound ranges from 0.30 wt. % to about 0.73 wt. % of total solids. In another aspect of this embodiment this heterocyclic thiol compound ranges from 0.30 wt. % to about 0.72 wt. % of total solids. In another aspect of this embodiment this heterocyclic thiol compound ranges from 0.30 wt. % to about 0.71 wt. % of total solids. In another aspect of this embodiment this heterocyclic thiol compound ranges from 0.30 wt. % to about 0.70 wt. % of total solids. In another aspect of this embodiment this heterocyclic thiol compound ranges from 0.30 wt. % to about 0.69 wt. % of total solids. In another aspect of this embodiment this heterocyclic thiol compound ranges from 0.30 wt. % to about 0.68 wt. % of total solids. In another aspect of this embodiment this heterocyclic thiol compound ranges from 0.30 wt. % to about 0.67 wt. % of total solids. In another aspect of this embodiment this heterocyclic thiol compound ranges from 0.30 wt. % to about 0.66 wt. % of total solids. In another aspect of this embodiment this heterocyclic thiol compound ranges from 0.30 wt. % to about 0.65 wt. % of total solids. In another aspect of this embodiment this heterocyclic thiol compound ranges from 0.30 wt. % to about 0.64 wt. % of total solids. In another aspect of this embodiment this heterocyclic thiol compound ranges from 0.30 wt. % to about 0.63 wt. % of total solids. In another aspect of this embodiment this heterocyclic thiol compound ranges from 0.30 wt. % to about 0.62 wt. % of total solids. In another aspect of this embodiment this heterocyclic thiol compound ranges from 0.30 wt. % to about 0.61 wt. % of total solids. In another aspect of this embodiment this heterocyclic thiol compound ranges from 0.30 wt. % to about 0.60 wt. % of total solids. In another aspect of this embodiment this heterocyclic thiol compound ranges from 0.30 wt. % to about 0.59 wt. % of total solids. In another aspect of this embodiment this heterocyclic thiol compound ranges from 0.30 wt. % to about 0.58 wt. % of total solids. In another aspect of this embodiment this heterocyclic thiol compound ranges from 0.30 wt. % to about 0.57 wt. % of total solids. In another aspect of this embodiment this heterocyclic thiol compound ranges from 0.30 wt. % to about 0.56 wt. % of total solids. In another aspect of this embodiment this heterocyclic thiol compound ranges from 0.30 wt. % to about 0.55 wt. % of total solids. In another aspect of this embodiment this heterocyclic thiol compound ranges from 0.30 wt. % to about 0.54 wt. % of total solids. In another aspect of this embodiment this heterocyclic thiol compound ranges from 0.30 wt. % to about 0.53 wt. % of total solids. In another aspect of this embodiment this heterocyclic thiol compound ranges from 0.30 wt. % to about 0.52 wt. % of total solids. In another aspect of this embodiment this heterocyclic thiol compound ranges from 0.30 wt. % to about 0.51 wt. % of total solids. In another aspect of this embodiment this heterocyclic thiol compound ranges from 0.30 wt. % to about 0.50 wt. % of total solids. In another aspect of this embodiment this heterocyclic thiol compound ranges from 0.30 wt. % to about 0.49 wt. % of total solids. In another aspect of this embodiment this heterocyclic thiol compound ranges from 0.30 wt. % to about 0.48 wt. % of total solids. In another aspect of this embodiment this heterocyclic thiol compound ranges from 0.30 wt. % to about 0.47 wt. % of total solids. In another aspect of this embodiment this heterocyclic thiol compound ranges from 0.30 wt. % to about 0.46 wt. % of total solids. In another aspect of this embodiment this heterocyclic thiol compound ranges from 0.30 wt. % to about 0.45 wt. % of total solids. In another aspect of this embodiment this heterocyclic thiol compound ranges from 0.30 wt. % to about 0.44 wt. % of total solids. In another aspect of this embodiment this heterocyclic thiol compound ranges from 0.30 wt. % to about 0.43 wt. % of total solids. In another aspect of this embodiment this heterocyclic thiol compound ranges from 0.30 wt. % to about 0.42 wt. % of total solids. In another aspect of this embodiment this heterocyclic thiol compound ranges from 0.30 wt. % to about 0.41 wt. % of total solids. In another aspect of this embodiment this heterocyclic thiol compound ranges from 0.30 wt. % to about 0.40 wt. % of total solids. In another aspect of this embodiment this heterocyclic thiol compound ranges from 0.30 wt. % to about 0.39 wt. % of total solids. In another aspect of this embodiment this heterocyclic thiol compound ranges from 0.30 wt. % to about 0.38 wt. % of total solids. In another aspect of this embodiment this heterocyclic thiol compound ranges from 0.30 wt. % to about 0.37 wt. % of total solids. In another aspect of this embodiment this heterocyclic thiol compound ranges from 0.31 wt. % to about 0.36 wt. % of total solids. In another aspect of this embodiment this heterocyclic thiol compound ranges from 0.32 wt. % to about 0.36 wt. % of total solids. In another aspect of this embodiment this heterocyclic thiol compound ranges from 0.32 wt. % to about 0.36 wt. % of total solids. In another aspect of this embodiment this heterocyclic thiol compound ranges from 0.33 wt. % to about 0.36 wt. % of total solids. In another aspect of this embodiment this heterocyclic thiol compound ranges from 0.34 wt. % to about 0.36 wt. % of total solids. In another aspect of this embodiment this heterocyclic thiol compound is about 0.35 wt. % of total solids.

Another aspect of this inventive composition is where component f), this heterocyclic thiol compound. as described herein, ranges from about 0.001 wt. % to about 1.5 wt. % of total solids. In another aspect of this embodiment, this heterocyclic thiol ranges from about 0.010 wt. % to about 1.5 wt. % of total solids. In another aspect of this embodiment this heterocyclic thiol ranges from about 0.1 wt. % to about 1.5 wt. % of total solids. In another aspect of this embodiment this heterocyclic thiol ranges from about 0.2 wt. % to about 1.5 wt. % of total solids. In another aspect of this embodiment this heterocyclic thiol ranges from about 0.3 wt. % to about 1.5 wt. % of total solids. In another aspect of this embodiment this heterocyclic thiol compound ranges from about 0.4 wt. % to about 1.5 wt. % of total solids. In another aspect of this embodiment this heterocyclic thiol ranges from about 0.6 wt. % to about 1.4 wt. % of total solids. In another aspect of this embodiment this heterocyclic thiol ranges from about 0.7 wt. % to about 1.3 wt. % of total solids. In another aspect of this embodiment said heterocyclic thiol compound ranges from about 0.8 wt. % to about 1.2 wt. % of total solids. In another aspect of this embodiment said heterocyclic thiol compound ranges from about 0.9 wt. % to about 1.1 wt. % of total solids. In another aspect of this embodiment said heterocyclic thiol compound is about 1 wt. % of total solids.

Another aspect of this inventive composition, as described herein, is where component g) the organic spin coating solvent component comprises one or more of butyl acetate, amyl acetate, cyclohexyl acetate, 3-methoxybutyl acetate, methyl ethyl ketone, methyl amyl ketone, cyclohexanone, cyclopentanonc, ethyl-3-ethoxy propanoate, methyl-3-ethoxy propanoate, methyl-3-methoxy propanoate, methyl acetoacetate, ethyl acetoacetate, diacetone alcohol, methyl pivalate, ethyl pivalate, propylene glycol monomethyl ether (PGME), propylene glycol monocthyl ether, propylene glycol monomethyl ether propanoate, propylene glycol monoethyl ether propanoate, ethylene glycol monomethyl ether, ethylene glycol monoethyl ether, diethylene glycol monomethyl ether, diethylene glycol monoethyl ether, 3-methyl-3-methoxybutanol, N-methylpyrrolidone, dimethyl sulfoxide, gamma-butyrolactone, propylene glycol methyl ether acetate (PGMEA), propylene glycol ethyl ether acetate, propylene glycol propyl ether acetate, methyl lactate, ethyl lactate, propyl lactate, tetramethylene sulfone, propylene glycol dimethyl ether, dipropylene glycol dimethyl ether, ethylene glycol dimethyl ether or diethylene glycol dimethyl ether and gamma butyrolactone. In one aspect of this embodiment said organic spin casting solvent in only one solvent. In another aspect of this embodiment said organic spin casting solvent is a mixture of two or more solvents. In another aspect it is a mixture of three solvents, in one aspect of this embodiment the solvent is a mixture of PGMEA, 3-methoxybutyl acetate and gamma-butyrolactone. In another aspect of this embodiment the solvent mixture is this mixture where PGMEA ranges from about 55 wt. % to about 80 wt. %, 3-methoxy butyl acetate ranges from about 5 wt. % to about 20 wt. %, and gamma butyrolactone ranges from about 1 wt. % to about 2 wt. %, where the sum of the wt. % of these individual components is equal to 100 wt. %.

### Optional Components

In one embodiment of the above-described inventive compositions it further comprises at least one optional surface leveling agents, such as one or more surfactants. In this embodiment, there is no particular restriction with regard to the surfactant, and the examples of it include a polyoxyethylene alkyl ether such as polyoxyethylene lauryl ether, polyoxyethylene stearyl ether, polyoxyethylene cetyl ether, and polyoxyethylene olein ether; a polyoxyethylene alkylaryl ether such as polyoxyethylene octylphenol ether and polyoxyethylene nonylphenol ether; a polyoxyethylene polyoxypropylene block copolymer; a sorbitane fatty acid ester such as sorbitane monolaurate, sorbitane monovalmitate, and sorbitane monostearate; a nonionic surfactant of a polyoxyethylene sorbitane fatty acid ester such as polyoxyethylene sorbitane monolaurate, polyoxyethylene sorbitanc monopalmitate, polyoxyethylene sorbitane monostearate, polyethylene sorbitane trioleate, and polyoxyethylene sorbitane tristearate; a fluorinated surfactant such as F-Top EF301, EF303, and EF352 (manufactured by Jemco Inc.), Megafac F171, F172, F173, R08, R30, R90, and R94 (manufactured by Dainippon Ink & Chemicals, Inc.), Florad FC-430, FC-431, FC-4430, and FC-4432 (manufactured by Sumitomo 3M Ltd.), Asahi Guard AG710, Surflon S-381, S-382, S-386, SC101, SC102, SC103, SC104, SC105, SC106, Surfinol E1004, KH-10, KH-20, KH-30, and KH-40 (manufactured by Asahi Glass Co., Ltd.); an organosiloxane polymer such as KP-341, X-70-092, and X-70-093 (manufactured by Shin-Etsu Chemical Co., Ltd.); and an acrylic acid or a methacrylic acid polymer such as Polyflow No. 75 and No. 95 (manufactured by Kyocisha Chemical Co. Ltd.). When a surfactant is present in one embodiment it ranges from about 0.01 wt. % to about 0.3 wt. % of total solids.

Said inventive composition when summing all solid components, a), b), c), d), c), f) and any optional solid components, such as surfactants, has a wt. % in solution as measure by the total wt, of solid components over the sum of these solid components and component g) said organic spin casting solvent which in one embodiment may range from about 20 wt. % to about 60 wt. %. In another embodiment it ranges from about 30 wt. % to about 55 wt. %. In another embodiment it ranges from about 35 wt. % to about 55 wt. %. In still another embodiment it ranges from about 40 wt. % to about 55 wt. %. In another embodiment it is about 50 wt. %.

Another aspect of this invention is a process of coating a substrate with any of the inventive composition as described herein. This coating process may be done by any method known in the art such as spin coating, spray coating, and blade coating. Another aspect of this invention is the use of the inventive composition as described herein for forming a photoresist.

Another aspect of this invention is a process for imaging a resist comprising the steps:
i) coating any one of the inventive compositions described herein on a substrate to form a resist film;
ii) selectively exposing the resist film to UV light using a mask to form a selectively exposed resist film;
iii) developing the selectively exposed film to form a positively imaged resist film over the substrate.
61. A process for imaging a resist comprising the steps;
ia) coating the composition of any one of the inventive compositions described herein on a substrate to form a resist film;
iia) selectively exposing the resist film to UV light using a mask to form a selectively exposed resist film; iiia) baking the selectively exposed resist film to form a baked selectively exposed resist film;
iva) developing the selectively exposed and baked resist film to form a positively imaged resist film over the substrate.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Chemicals

Unless otherwise indicated all chemicals were obtained from Millipore Sigma.

### Coating of Formulations

All formulations were tested on 6 or 8″ diameter Si and Cu wafers. The Si wafers were rehydration baked and vapor primed with hexamethyldisilazane (HMDS). The Cu wafers were silicon wafers coated with 5,000 Angstroms of silicon dioxide, 250 Angstroms of tantalum nitride, and 3,500 Angstroms of Cu (PVD deposited).

The resist coatings were prepared by spin coating the resist samples and applying a soft bake for 120 seconds at 110° C. on standard wafer track hot plate in contact mode. The spin speed was adjusted to obtain 5 to 10-microns thick resist films. All film thickness measurements were conducted on Si wafers using optical measurements.

### Imaging

The wafers were exposed on SUSS MA200 CC Mask Aligner or on ASML 250 i-line stepper. The resist was waited for 10-60 mins without post exposure baking and then puddle developed for 120 to 360 seconds in AZ 300 MIF (0.26N aqueous solution of tetramethyl ammonium hydroxide=TMAH) at 23° C. The developed resist images were inspected using Hitachi S4700 or AMRAY 4200L electron microscopes.

### Materials

### Synthesis Radom Copolymer of Structure (B)

The following examples show the synthesis of random copolymer of structure (B) which were used as component b) in the rested formulations. The associated structures showed the proportions of the repeat units in the isolated copolymers in mole %.

### Synthesis Example Copolymer of structure (B) Example 1 (CPB-1)

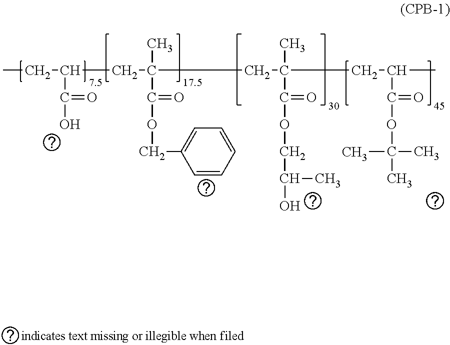

In this example, 4.32 g of acrylic acid, 24.67 g of benzyl methacrylate, 34.60 g of hydroxypropyl methacrylate, 46.14 g of tert-butyl acrylate were mixed in 207.1 g of PGME solvent. The polymerization reaction proceeded in the presence of 1.84 g of AIBN at 90° C., under nitrogen for 18 hours. After cooling down to room temperature, the reaction mixture was precipitated in DI water. The polymer solid was washed and dried under vacuum at 45° C., yielding 107.3 g (98% yield) with a weight average molecular weight of 16,138 Daltons and a number average molecular weight of 8,207 Daltons.

### Synthesis Example Copolymer of Structure (B) Example 2 (CPB-2)

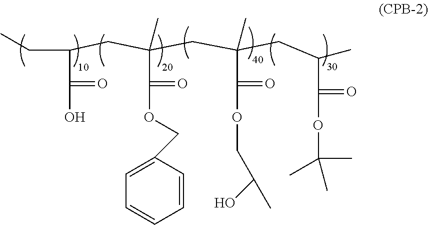

In this example, 7.2 g of acrylic acid, 35.24 g of benzyl methacrylate, 57.67 g of hydroxypropyl methacrylate, 38.45 g of tert-butyl acrylate were mixed in 138.56 g of PGME solvent. The polymerization reaction proceeds in the presence of 1.64 g of AIBN at 90° C., under nitrogen for 18 hours. After cooling down to room temperature, the reaction mixture was precipitated in DI water. The polymer solid was washed and dried under vacuum at 45° C., yielding 135.8 g (98% yield) with a weight average molecular weight of 39,998 Daltons and a number average molecular weight of 16987 Daltons.

### Synthesis Example Copolymer of structure (B) Example 3 (CPB-3)

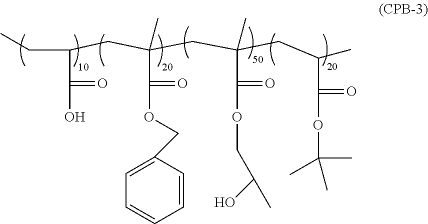

In this example, 7.2 g of acrylic acid, 35.24 g of benzyl methacrylate, 72.09 g of hydroxypropyl methacrylate, 25.63 g of tert-butyl acrylate were mixed in 140.56 g of PGME solvent. The polymerization reaction proceeds in the presence of 1.64 g of AIBN at 90° C., under nitrogen for 18 hours. After cooling down to room temperature, the reaction mixture was precipitated in DI water. The polymer solid was washed and dried under vacuum at 45° C., yielding 137.4 g (98% yield) with a weight average molecular weight of 32,439 Daltons and a number average molecular weight of 13090 Daltons.

### Synthesis Example Copolymer of Structure (B) Example 4 (CPB-4)

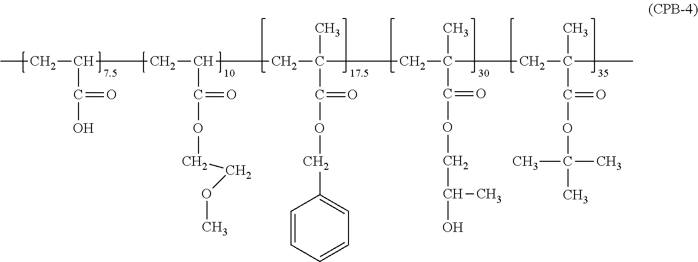

In this example, 2.7 g of acrylic acid, 6.5 g of methoxyethyl acylate, 15.4 g of benzyl methacrylate, 21.6 g of hydroxypropyl methacrylate, 24.9 g of tert-butyl methacrylate were mixed in 135.2 g of PGME solvent. The polymerization reaction proceeded in the presence of 1.6 g of AIBN at 90° C., under nitrogen for 18 hours. After cooling down to room temperature, the reaction mixture was precipitated in DI water. The white polymer solid was washed and dried under vacuum at 45° C., yielding 70.3 g (99% yield) with a weight average molecular weight of 17,153 Daltons and a number average molecular weight of 8,707 Daltons.

### Synthesis Example Copolymer of Structure (B) Example 5 (CPB-5)

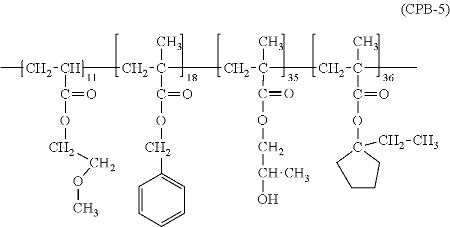

In this example, 7.16 g of methoxyethyl acrylate, 15.86 g of benzyl methacrylate, 25.23 g of hydroxypropyl methacrylate, 32.78 g of 1-ethylcyclopentyl methacrylate (Osaka Organic Chemical Industry LTD, Osaka, Japan) were mixed in 152.6 g of PGME solvent. The polymerization reaction proceeded in the presence of 1.2 g of AIBN at 90° C., under nitrogen for 18 hours. After cooling down to room temperature, the reaction mixture was precipitated in DI water. The polymer solid was washed and dried under vacuum at 45° C., yielding 79.3 g (98% yield) with a weight average molecular weight of 17,985 Daltons and a number average molecular weight of 10,278 Daltons.

### Synthesis Example Copolymer of Structure (B) Example 6 (CPB-6)

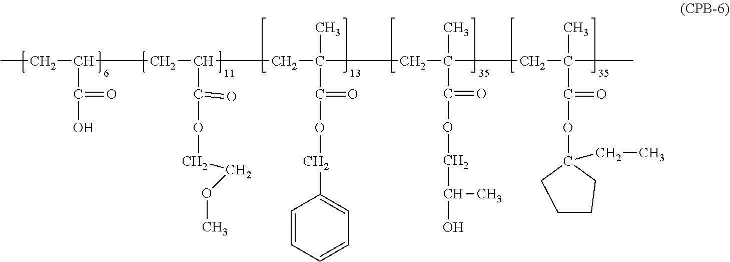

4.32 g of acrylic acid, 14.32 g of methoxyethyl acylate, 22.91 g of benzyl methacrylate, 50.46 g of hydroxypropyl methacry late, 63.75 g of 1-ethylcyclopentyl methacrylate are mixed in 158.5 g of PGME solvent. The polymerization reaction proceeds in the presence of 2.71 g of AIBN at 90° C., under nitrogen for 18 hours. After cooling down to room temperature, the reaction mixture is precipitated in DI water. The polymer solid is washed and dried under vacuum at 45° C., yielding 153.45 g (98.5% yield) with a GPC (polystyrene standard) weight average molecular weight of 17,103 Daltons and a number average molecular weight of 8316 Daltons.

### Synthesis Example Copolymer of Structure (B) Example 7 (CPB-7)

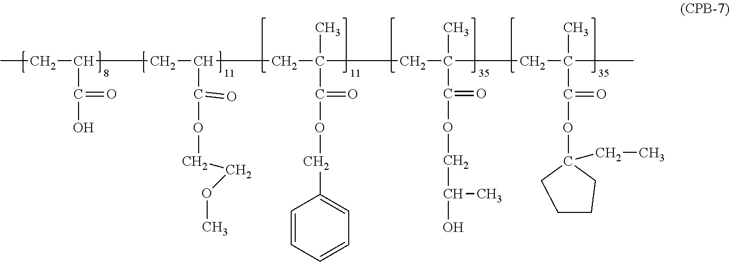

In this example, 5.76 g of acrylic acid, 14.32 g of methoxyethyl acylate, 19.38 g of benzyl methacrylate, 50.46 g of hydroxypropyl methacrylate, 63.75 g of 1-ethylcyclopentyl methacrylate are mixed in 156.4 g of PGME solvent. The polymerization reaction proceeds in the presence of 2.71 g of AIBN at 90° C., under nitrogen for 18 hours. After cooling down to room temperature, the reaction mixture is precipitated in DI water. The polymer solid is washed and dried under vacuum at 45° C., yielding 150.2 g (97.7% yield) with a GPC (polystyrene standard) weight average molecular weight of 15,557 Daltons and a number average molecular weight of 7795 Daltons.

### Synthesis Example Copolymer of Structure (B) Example 8 (CPB-8)

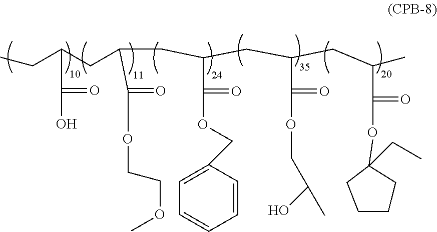

In this example, 7.2 g of acrylic acid, 14.31 g of methoxyethyl acylate, 42.29 g of benzyl methacrylate, 50.46g of hydroxypropyl methacrylate, 36.43 g of 1-ethylcyclopentyl methacrylate are mixed in 150.7 g of PGME solvent. The polymerization reaction proceeds in the presence of 1.97 g of AIBN at 90° C., under nitrogen for 18 hours. After cooling down to room temperature, the reaction mixture is precipitated in DI water. The polymer solid is washed and dried under vacuum at 45° C., yielding 147.2 g (97.7% yield) with a GPC (polystyrene standard) weight average molecular weight of 35913 Daltons and a number average molecular weight of 16541 Daltons.

### Synthesis Example Copolymer of Structure (B) Example 9 (CPB-9)

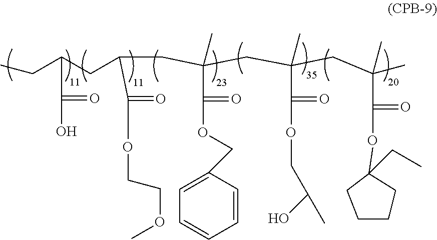

In this example, 7.93 g of acrylic acid, 14.31 g of methoxyethyl acylate, 40.53 g of benzyl methacrylate, 50.46 g of hydroxypropyl methacrylate, 36.43 g of 1-ethylcyclopentyl methacrylate are mixed in 149.66 g of PGME solvent. The polymerization reaction proceeds in the presence of 2.46 g of AIBN at 90° C., under nitrogen for 18 hours. After cooling down to room temperature, the reaction mixture is precipitated in DI water. The polymer solid is washed and dried under vacuum at 45° C., yielding 146.7 g (98% yield) with a GPC (polystyrene standard) weight average molecular weight of 36037 Daltons and a number average molecular weight of 15251 Daltons.

### Synthesis Example Copolymer of Structure (B) Example 10 (CPB-10)

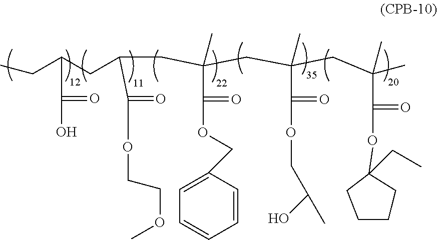

In this example, 8.65 g of acrylic acid, 14.31 g of methoxyethyl acylate, 38.77 g of benzyl methacrylate, 50.46 g of hydroxypropyl methacrylate, 36.43 g of 1-ethylcyclopentyl methacrylate are mixed in 148.6 g of PGME solvent. The polymerization reaction proceeds in the presence of 2.30 g of AIBN at 90° C., under nitrogen for 18 hours. After cooling down to room temperature, the reaction mixture is precipitated in DI water. The polymer solid is washed and dried under vacuum at 45° C., yielding 145.6 g (98% yield) with a GPC (polystyrene standard) weight average molecular weight of 26086 Daltons and a number average molecular weight of 12854 Daltons.

### Synthesis Example Copolymer of Structure (B) Example 11 (CPB-11)

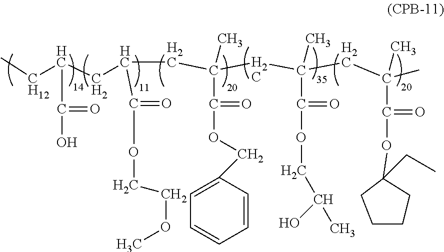

In this example, 10.09 g of acrylic acid, 14.31 g of methoxyethyl acylate, 35.24 g of benzyl methacrylate, 50.46 g of hydroxypropyl methacrylate, 36.43 g of 1-ethylcyclopentyl methacrylate are mixed in 146.5 g of PGME solvent. The polymerization reaction proceeds in the presence of 2.30 g of AIBN at 90° C., under nitrogen for 18 hours. After cooling down to room temperature, the reaction mixture is precipitated in DI water. The polymer solid is washed and dried under vacuum at 45° C., yielding 144.6 g (98.7% yield) with a GPC (polystyrene standard) weight average molecular weight of 30206 Daltons and a number average molecular weight of 12269 Daltons.

### Synthesis Example Copolymer of Structure (B) Example 12 (CPB-12)

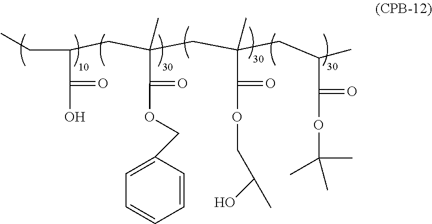

In this example, 7.28 g of acrylic acid, 53.60 g of benzyl methacrylate, 43.32 g of hydroxypropyl methacry late, 38.83 g of tert-Butyl acrylate are mixed in 141 g of PGMEA solvent. The polymerization reaction proceeds in the presence of 2.46 g of AIBN at 90° C., under nitrogen for 20 hours. After cooling down to room temperature, the reaction mixture was directed for further use. Theoretically, this allows the final polymer product having a wt. % of solids in the spin casting solvent PGMEA of 50 wt. %, which was used to prepare a formulation solution as is. A small amount (˜2 g) of the product was precipitated in DI water. The polymer solid from the precipitation was washed and dried under vacuum at 50° C. The vacuum-dried product was characterized with a GPC (polystyrene standard). The measured weight average molecular weight of was 28661 Daltons and the number average molecular weight was 10293 Daltons.

### Synthesis Example Copolymer of Structure (B) Example 13 (CPB-13)

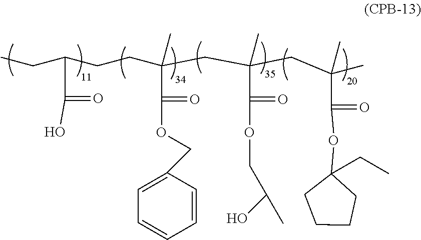

In this example, 7.93 g of acrylic acid, 59.95 g of benzyl methacrylate, 50.49 g of hydroxypropyl methacrylate, 36.45 g of 1-ethylcyclopentyl methacrylate are mixed in 158 g of PGMEA solvent. The polymerization reaction proceeds in the presence of 2.46 g of AIBN at 90° C., under nitrogen for 20 hours. After cooling down to room temperature, the reaction mixture was directed for further use. Theoretically, this allows the final polymer product having a wt. % of solids in the spin casting solvent PGMEA of 50 wt. %, which was used to prepare a formulation solution as is. A small amount (˜2 g) of the product was precipitated in DI water. The polymer solid from the precipitation was washed and dried under vacuum at 50° C. The vacuum-dried product was characterized with a GPC (polystyrene standard). The measured weight average molecular weight was 32272 Daltons, and the number average molecular weight was 13253 Daltons.

### Synthesis Example Copolymer of Structure (B) Example 14 (CPB-14)

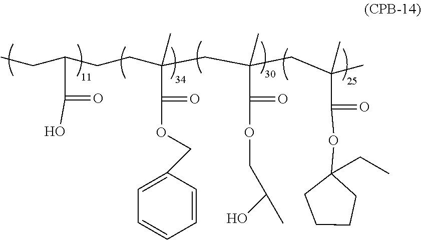

In this example, 7.92 g of acrylic acid, 59.99 g of benzyl methacrylate, 43.19 g of hydroxypropyl methacrylate, 45.72 g of 1-ethylcyclopentyl methacrylate are mixed in 156 g of PGMEA solvent. The polymerization reaction proceeds in the presence of 2.46 g of AIBN at 90° C., under nitrogen for 20 hours. After cooling down to room temperature, the reaction mixture was directed for further use. Theoretically, this allows the final polymer product having a wt. % of solids in the spin casting solvent PGMEA of 50 wt. %, which was used to prepare a formulation solution as is. A small amount (˜2 g) of the product was precipitated in DI water. The polymer solid from the precipitation was washed and dried under vacuum at 50° C. The vacuum-dried product was characterized with a GPC (polystyrene standard). The measured weight average molecular weight was 29183 Daltons, and the number average molecular weight was 11834 Daltons.

### Synthesis Example Copolymer of Structure (B) Example 15 (CPB-15)

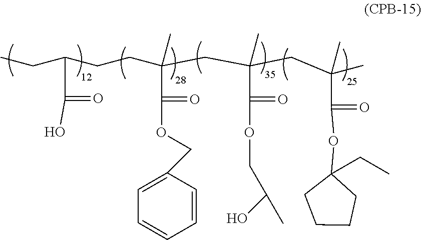

In this example, 8.65 g of acrylic acid, 49.35 g of benzyl methacrylate, 50.46 g of hydroxypropyl methacrylate, 45.60 g of 1-ethylcyclopentyl methacrylate are mixed in 154 g of PGMEA solvent. The polymerization reaction proceeds in the presence of 2.46 g of AIBN at 90° C., under nitrogen for 20 hours. After cooling down to room temperature, the reaction mixture was directed for further use. Theoretically, this allows the final polymer product having a wt. % of solids in the spin casting solvent PGMEA of 50 wt. %, which was used to prepare a formulation solution as is. A small amount (˜2 g) of the product was precipitated in DI water. The polymer solid from the precipitation was washed and dried under vacuum at 50° C., characterized with a GPC (polystyrene standard). The measured weight average molecular weight was 25414 Daltons, and the number average molecular weight was 11894 Daltons.

### Synthesis Example Copolymer of Structure (B) Example 16 (CPB-16)

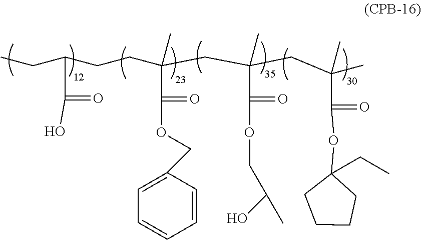

In this example, 8.67 g of acrylic acid, 40.52 g of benzyl methacrylate, 50.47 g of hydroxypropyl methacrylate, 54.68 g of 1-ethylcyclopentyl methacrylate are mixed in 158 g of PGMEA solvent. The polymerization reaction proceeds in the presence of 2.46 g of AIBN at 90° C., under nitrogen for 20 hours. After cooling down to room temperature, the reaction mixture was directed for further use. Theoretically, this allows the final polymer product having a wt. % of solids in the spin casting solvent PGMEA of 50 wt. %, which was used to prepare a formulation solution as is. A small amount (˜2 g) of the product was precipitated in DI water. The polymer solid from the precipitation was washed and dried under vacuum at 50° C. The vacuum-dried product was characterized with a GPC (polystyrene standard). The weight average molecular weight was 26763 Daltons, and the number average molecular weight was 11560 Daltons.

### Synthesis Example Copolymer of Structure (B) Example 17 (CPB-17)

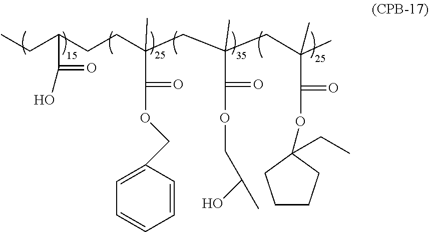

In this example, 10.80 g of acrylic acid, 44.06 g of benzyl methacrylate, 50.48 g of hydroxypropyl methacrylate, 45.57 g of 1-ethylcyclopentyl methacrylate are mixed in 151 g of PGMEA solvent. The polymerization reaction proceeds in the presence of 2.46 g of AIBN at 90° C., under nitrogen for 20 hours. After cooling down to room temperature, the reaction mixture was directed for further use. Theoretically, this allows the final polymer product having a wt. % of solids in the spin casting solvent PGMEA of 50 wt. %, which was used to prepare a formulation solution as is. A small amount (˜2 g) of the product was precipitated in DI water. The polymer solid from the precipitation was washed and dried under vacuum at 50° C. The vacuum-dried product was characterized with a GPC (polystyrene standard). The weight average molecular weight was 32591 Daltons, and a number average molecular weight was 14187 Daltons.

### Synthesis Example Copolymer of Structure (B) Example 18 (CPB-18)

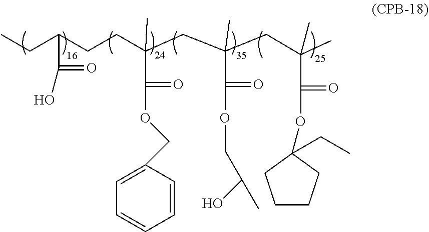

In this example, 30.74 g of acrylic acid, 112.92 g of benzyl methacrylate, 134.72 g of hydroxypropyl methacrylate, 121.73 g of 1-ethylcyclopentyl methacrylate are mixed in 600 g of PGME solvent. The polymerization reaction proceeds in the presence of 7.23 g of AIBN at 90° C., under nitrogen for 20 hours. After cooling down to room temperature, the reaction mixture is precipitated in DI water. The polymer solid is washed and dried under vacuum at 45° C., yielding 397.7g (98% yield). The vacuum-dried polymer was characterized with a GPC (polystyrene standard). The weight average molecular weight was 20772 Daltons, and the number average molecular weight was 7795 Daltons.

### Synthesis Example Copolymer of Structure (B) Example 19 (CPB-19)

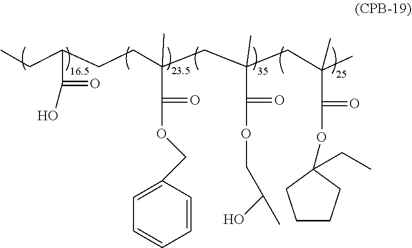

In this example, 11.92 g of acrylic acid, 41.42 g of benzyl methacrylate, 50.46 g of hydroxypropyl methacrylate, 47.81 g of 1-ethylcyclopentyl methacrylate are mixed in 150 g of PGME solvent. The polymerization reaction proceeds in the presence of 2.70g of AIBN at 90° C., under nitrogen for 20 hours. After cooling down to room temperature, the reaction mixture was directed for further use. Theoretically, this allows the final polymer product having a wt. % of solids in the spin casting solvent PGMEA of 50 wt. %, which was used to prepare a formulation solution as is. A small amount (˜2 g) of the product was precipitated in DI water. The polymer solid from the precipitation was washed and dried under vacuum at 50° C. The vacuum-dried product was characterized with a GPC (polystyrene standard). The weight average molecular weight was 32898 Daltons, and the number average molecular weight was 9249 Daltons.

### Synthesis Example Copolymer of Structure (B) Example 20 (CPB-20)

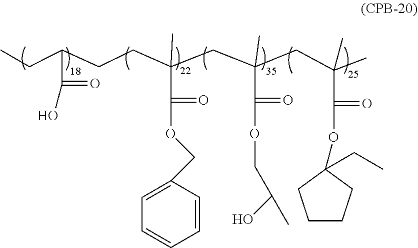

In this example, 13.00 g of acrylic acid, 38.78 g of benzyl methacrylate, 50.46 g of hydroxypropyl methacrylate, 45.57 g of 1-ethylcyclopentyl methacrylate are mixed in 149 g of PGMEA solvent. The polymerization reaction proceeds in the presence of 2.46 g of AIBN at 90° C., under nitrogen for 20 hours. After cooling down to room temperature, the reaction mixture was directed for further use. Theoretically, this allows the final polymer product having a wt. % of solids in the spin casting solvent PGMEA of 50 wt. %, which was used to prepare a formulation solution as is. A small amount (˜2 g) of the product was precipitated in DI water. The polymer solid from the precipitation was washed and dried under vacuum at 50° C. The vacuum-dried product was characterized with a GPC (polystyrene standard). The weight average molecular weight was 27168 Daltons, and the number average molecular weight was 10081 Daltons.

### Synthesis Examples for Copolymer of Structure (A) with High Dissolution Rates

The two following examples are acrylic polymer were made and tested in the following formulations as component a) the Copolymer of structure (A)

### Synthesis of Copolymer of Structure (A) Example 1. (CPA-1)

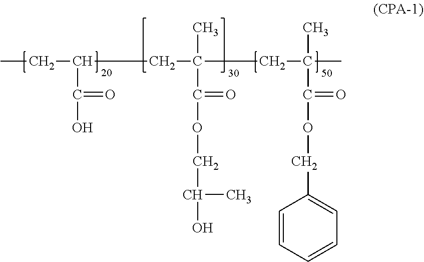

In this example, 7.21 g of acrylic acid, 21.62 g of hydroxypropyl methacrylate, 44.05 g of benzyl methacrylate were mixed in 138.4 g of PGME solvent. The polymerization reaction proceeded in the presence of 1.6 g of AIBN at 90° C., under nitrogen for 18 hours. After cooling down to room temperature, the reaction mixture was precipitated in DI water. The white polymer solid was washed and dried under vacuum at 50° C., yielding 71.4 g (98% yield) with a weight average molecular weight of 15929 Daltons, and had a dissolution rate in of 920 Å/sec in 0.26 aqueous TMAH at 23° C.

### Synthesis Polymer Class B Alkali Soluble Resin Example 2 (CPA-2)

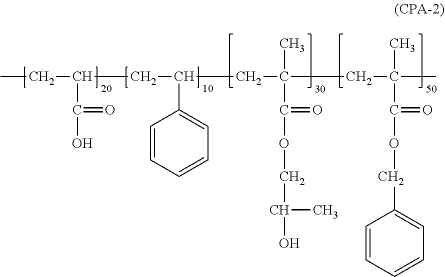

In this example, 9.01 g of acrylic acid, 5.21 g of styrene, 21.62 g of hydroxypropyl methacrylate, 30.84g of benzyl methacrylate were mixed in 126.9 g of PGME solvent. The polymerization reaction proceeded in the presence of 1.64 g of AIBN at 90° C., under nitrogen for 18 hours. After cooling down to room temperature, the reaction mixture was precipitated in DI water. The white polymer solid was washed and dried under vacuum at 50° C. yielding 64.9 g (97% yield) with a weight average molecular weight of 15314 Daltons and a number average molecular weight of 7843 Daltons, and had a dissolution rate in of 840 Å/sec in 0.26 aqueous TMAH at 23° C.

### Commercially Available Acrylic Polymer with High Dissolution Rate

Table 1 shows a listing of commercial carboxylic acid containing resins which were also used as component a), random copolymer, having structure (A), and their characteristics, these were employed in Formulations 1 to 80. These materials have a fast dissolution rate in 0.26 N TMAH aqueous developer at room temperature (23° C.). For examples Joncryl817 was measured to have a dissolution rate of 1780 Å/s.

TABLE 1
Commercial Monocryl resin with high dissolution rate

| Component | Name | St/AA | Manufacturer |
|---|---|---|---|
| Joncryl 817 | acrylic acid-styrene copolymer | 60/40 | BASF |
| | (MW = 14000) | | |
| Joncryl 819 | acrylic acid-styrene copolymer | 50/50 | BASF |
| | (MW = 15000) | | |
| Joncryl 822 | acrylic acid-styrene copolymer | 50/50 | BASF |
| | (MW = 10500) | | |

### Novolak Polymers

For the following formulation examples, three Novolak polymers were employed Novolak-1, Novolak-2 and Novolak-3 were used as component c), the Novolak polymer. These polymers were based on commercially available Novolak polymers (Allnex (Alpharetta, Ga) derived from meta-cresol and formaldehyde were employed. Novolak 1 was “ALNOVOL™ SPN 560/47MPAC SLOW,” Mw 24010, D: 7.3 which had a bulk dissolution rate in 0.26 N aqueous TMAH developer of 700 Å/sec; Novolak-2 was “ALNOVOL™ SPN 560/47MPAC FAST,” Mw 7,245, D: 4.8 which had a bulk dissolution rate in 0.26 N aqueous TMAH developer of 1,600 Å/sec. Novolak 3 was 1/1 blend of Novolak-1 and Novolak.

### Base Additive

The base additive employed in the following formulations was mono-tribuylammonium salt of oxalic acid (tributylammonium oxalate). Mono-tributylammonium oxalate was prepared according to US20190064662A1 as described in Synthesis example 1.

### Formulation Examples

### Formulation Example 1

In this example, 17.325 g polymer of Synthesis Example 1 (CPM-1), 21.753 g of Novolak-3, 9.90 g of Joncryl 817 (BASF), 0.248 g of 1,3-dioxo-1H-benzo[de]isoquinolin-2 (3H)-yl trifluoromethanesulfonate [also called naphthalene dicarboximidyl triflate, NIT] (NIT PAG), 0.173 g 5-Mercapto-1-Phenyl-1H-Tetrazole (PMT) (from TCI), 0.0025 g of tetrabutyl ammonium oxalate (Merck KGaA, PM-I, Wiesbaden, Germany), 0.099 g of APS-437 (also called KF353A) (ShinEtsu Chemical Co. LTd, Tokyo, Japan company) were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 2

In this example. 17.325 g polymer of Synthesis Example 2 (CPM-2), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 3

In this example, 17.325 g polymer of Synthesis Example 3 (CPM-3), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 4

17.325 g polymer of Synthesis Example 4 (CPM-4), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 5

In this example, 17.325 g polymer of Synthesis Example 5 (CPM-5), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 6

In this example, 17.325 g polymer of Synthesis Example 6 (CPM-6), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 7

In this example, 17.325 g polymer of Synthesis Example 7 (CPM-7), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 8

17.325 g polymer of Synthesis Example 8 (CPM-8), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 9

In this example, 17.325 g polymer of Synthesis Example 9 (CPM-9), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 10

In this example, 17.325 g polymer of Synthesis Example 10 (CPM-10), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 11

In this example, 17.325 g polymer of Synthesis Example 11 (CPM-11), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 12

In this example, 34.65 g polymer solution of Synthesis Example 12 (CPM-12), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 20.919 g of PGMEA, 10.24 g 3-methoxybutyl acetate and 2.016 g γ-Butyrolactone (GBL) mixed solvents to make a solution. The solution was filtered for lithographic test.

Formulation Example 13

In this example, 34.65 g polymer solution of Synthesis Example 13 (CPM-13), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 20.919 g of PGMEA, 10.24 g 3-methoxybutyl acetate and 2.016 g γ-Butyrolactone (GBL) mixed solvents to make a solution. The solution was filtered for lithographic test.

### Formulation Example 14

In this example, 34.65 g polymer solution of Synthesis Example 14 (CPM-14), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 20.919 g of PGMEA, 10.24 g 3-methoxybutyl acetate and 2.016 g γ-Butyrolactone (GBL) mixed solvents to make a solution. The solution was filtered for lithographic test.

### Formulation Example 15

In this example, 34.65 g polymer solution of Synthesis Example 15 (CPM-15), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 20.919 g of PGMEA, 10.24 g 3-methoxybutyl acetate and 2.016 g γ-Butyrolactone (GBL) mixed solvents to make a solution. The solution was filtered for lithographic test.

### Formulation Example 16

In this example, 34.65 g polymer solution of Synthesis Example 16 (CPM-16), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 20.919 g of PGMEA, 10.24 g 3-methoxybutyl acetate and 2.016 g γ-Butyrolactone (GBL) mixed solvents to make a solution. The solution was filtered for lithographic test.

### Formulation Example 17

In this example, 34.65 g polymer solution of Synthesis Example 17 (CPM-17), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 20.919 g of PGMEA, 10.24 g 3-methoxybutyl acetate and 2.016 g γ-Butyrolactone (GBL) mixed solvents to make a solution. The solution was filtered for lithographic test.

### Formulation Example 18

In this example, 17.325 g polymer of Synthesis Example 18 (CPM-18), 21.753 g of Novolak-3, 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Formulation Example 19

In this example, 34.65 g polymer solution of Synthesis Example 19 (CPM-19), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 20.919 g of PGMEA, 10.24 g 3-methoxybutyl acetate and 2.016 g γ-Butyrolactone (GBL) mixed solvents to make a solution. The solution was filtered for lithographic test.

### Formulation Example 20

In this example, 34.65 g polymer solution of Synthesis Example 18 (CPM-20), 21.753 g of Novolak-3, 9.90 g of Joncryl 817, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 20.919 g of PGMEA, 10.24 g 3-methoxybutyl acetate and 2.016 g γ-Butyrolactone (GBL) mixed solvents to make a solution. The solution was filtered for lithographic test.

### Formulation Examples 21-40

In Formulation Examples 20-40 the same components were used as in Formulations Examples 1 to 20 except that Joncryl 817 was replaced with Joncryl 822

### Formulation Examples 41-60

In Formulation Examples 41-60 the same components were used as in Formulations Examples 1 to 20 except that Joncryl 817 was replaced with Synthesis of Copolymer of Structure (A) Example 1 (CPA-1).

### Formulation Examples 61-80

In Formulation Examples 61-80 the same components were used as in Formulations Examples 1 to 20 except that Joncryl 817 was replaced with Joncryl 819.

### Comparative Formulation Example without Joncryl and CPA Copolymer

17.325 g polymer of Synthesis Example 7 (CPB-7), 31.653 g of Novolak-3, 0.248 g of NIT PAG, 0.173 g 5-Mercapto-1-Phenyl-1H-Tetrazole (PMT), 0.0025 g of tetrabutyl ammonium oxalate, 0.099 g of APS-437 were dissolved in 38.244 g of PGMEA, 10.24 g 3-methoxybutyl acetate and 2.016 g γ-Butyrolactone (GBL) mixed solvents to make a solution. The solution was filtered for lithographic test.

### Coating with Formulations

All formulations were tested on 8″ diameter Si and Cu wafers. The Si wafers were dehydration baked and vapor primed with hexamethyldisilazane (HMDS).

The resist coatings were prepared by spin coating the resist samples and applying a soft bake for 360 seconds at 140° C. on standard wafer track hot plate in contact mode. The spin speed was adjusted to obtain 60-micron thick resist films. The double coating was applied for obtaining 150-200 micron film thickness. All film thickness measurements were conducted on Si wafers using optical measurements.

### Imaging of Coated Wafers

The coated wafers were exposed on SUSS MA200 CC Mask Aligner or on ORC i-line stepper. The wafer was baked at 100° C. for 100 second and then puddle developed for 120-360 seconds in AZ 300 MIF (0.26N aqueous solution of tetramethyl ammonium hydroxide=TMAH) at 23° C. The developed resist images were inspected using Hitachi S4700 or AMRAY 4200L electron microscopes.

Table 2 shows the Lithographic testing results which were obtained, for 60-micron film thickness imaged on a SUSS contact printer. With 20 wt. % loading in total solid of Joncryl 817, Joncryl 822, CPA-1 and CPA-2, the photo-speed was increased about 40% compared to that without those components. Copolymers of Joncryl and CPA additives served as photo-speed enhancer and also decreased the contact angle of the film with water by 10 degrees. With t-butyl (tert Bu) group as cleavable group, the photo-speed is slower than that of 1-ethyl cyclopentyl (EtCp) group. The photo-speed was observed to be getting faster with increasing EtCp mole % and increasing Carboxylic acid mole %. When acrylic acid mole % was over 10%, the dark film loss appeared, which was very small (˜1 micron) and did not hinder the imaging capability and had the advantage of further increasing the hydrophilicity of the film and consequently further improving the wettability of these formulations towards the substrate.

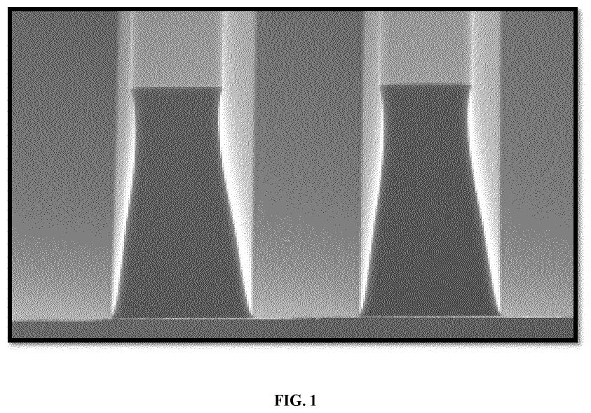

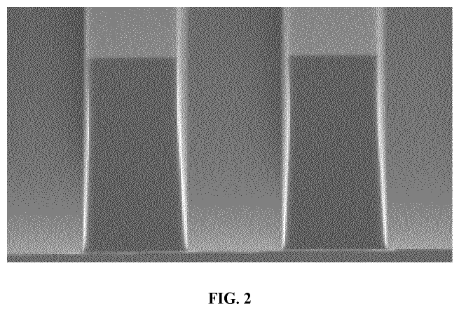

FIG. 1 and FIG. 2 show, respectively, SEM pictures of images obtained with Comparative Formulation was imaged at a dose of 500 mJ/cm² and Formulation 7. As seen in FIG. 1 the comparative sample gave poor imaging with very sloped profiles. In contract as seen in FIG. 2F which showed good resolution of 40-micron L/S features that were vertical and obtained at a dose of 300 mJ/cm² on a SUSS contact printer.

TABLE 1
Test results for Formulations at 60 um film thickness

| Copolymer | Copolymer | Copolymer | | | | |
|---|---|---|---|---|---|---|
| of | of | of | Acid | | | |
| structure | structure | structure | labile | | | |
| (B) | (B) Acrylic | (B) Acid | group | | E₀* | Dark |
| Example | Acid Unit | Labile | mole | Formulation | (mJ/ | Film |
| # | mole % | group | % | Examples | cm²) | Loss** |
| 1 | 7.5 | t-Bu | 45 | 1, 21, 41, 61, | 400 | No |
| 2 | 10 | t-Bu | 30 | 2, 22, 42, 62, | 400 | No |
| 3 | 10 | t-Bu | 20 | 3, 23, 43, 63, | 400 | No |
| 4 | 7.5 | t-Bu | 35 | 4, 24, 44, 64, | 400 | No |
| 5 | 0 | EtCp | 36 | 5, 25, 45, 65, | 260 | No |
| 6 | 6 | EtCp | 35 | 6, 26, 46, 66, | 240 | No |
| 7 | 8 | EtCp | 35 | 7, 27, 47, 67, | 240 | No |
| 8 | 10 | EtCp | 20 | 8, 28, 48, 68, | 200 | No |
| 9 | 11 | EtCp | 20 | 9, 29, 49, 69, | 200 | Yes |
| 10 | 12 | EtCp | 20 | 10, 39, 50, | 160 | Yes |
| | | | | 70 | | |
| 11 | 14 | EtCp | 20 | 11, 31, 51, | 160 | Yes |
| | | | | 71, | | |
| 12 | 10 | tBA | 30 | 12, 42, 52, | 400 | No |
| | | | | 72, | | |
| 13 | 11 | EtCp | 20 | 13, 43, 53, | 200 | No |
| | | | | 73, | | |
| 14 | 11 | EtCp | 25 | 14, 44, 54, | 200 | No |
| | | | | 74, | | |
| 15 | 12 | EtCp | 25 | 15, 45, 55, | 200 | Yes |
| | | | | 75, | | |
| 16 | 12 | EtCp | 30 | 16, 46, 56, | 160 | Yes |
| | | | | 76, | | |
| 17 | 15 | EtCp | 25 | 17, 47, 57, | 160 | Yes |
| | | | | 77, | | |
| 18 | 16 | EtCp | 25 | 18, 48, 58, | 160 | Yes |
| | | | | 78, | | |
| 19 | 16.5 | EtCp | 25 | 19, 49, 59, | 160 | Yes |
| | | | | 79, | | |
| 20 | 18 | EtCp | 25 | 20, 50, 60, | 160 | Yes |
| | | | | 80, | | |

*E₀: first dose to open the pattern. Dark Film Loss: film thickness change in unexposed wafer treated with developer for 4 × 60 sec.
**“No,” entails that dark film loss in unexposed areas was not detectable, “Yes,” means that a dark film loss of less than 1 micron was detected which did not affect the resolution capability of the photoresist formulation.

FIG. 1 shows the images obtained with the comparative example which had the almost the same formulation as Formulation 7 in Table 1, but which exclude a Joncryl, or CPA copolymers additive [a.k.a. Component a)]. The image observed in FIG. 1 showed considerable sloping of L/S features and was obtained at a much higher dose 400 mJ/cm² compared to the straight wall profiles obtained with Formulation 7 as shown in FIG. 2 at a dose of only 240 mJ/cm². The images shown in FIGS. 1 and 2 were obtained under the same processing condition in films which were 80-micron film thickness, after a soft baking at 140° C. for 360 seconds, a post exposure baking at 90° C. for 100 seconds and a develop time 6×50sec in 0.26 N TMAH aqueous developer.

### Wettability Contact Angle Measurements

Wettability a property which was unexpectedly related the imaging capability of these formulations was evaluated by a static water contact angle. The resist film was coated and baked at 140° C. for 360 seconds, then soaked with developer for 60 sec. The contact angle of the film was determined with Dataphysics Contact Angle System OCA. The comparative formulation has a static water contact angle of 81°. As comparison, after introducing either Joncryl derivates or CPA copolymers to the formulations this led to a ˜5 to 10° decrease of the contact angle the formulation example improving their wettability. For example, Formulation 7 containing Joncryl 817 had a measured static contact angle of 75°. Formulation 47, containing CPA-1 also had a contact angle of 75°. Similar effects were observed in the formulations containing CPA-2, Joncryl 819, and Joncryl 822.

Another, aspect of these formulation which was observed that decreased contact angle and increase wettability was to increase the acrylic acid repeat unit loading in the CPB component in these formulations. For example, Formulation 20 formulated with CPB-20, a copolymer with 18 mole % acrylic acid repeat units had a contact angle of 70° compared to Formulation 7 whose only difference was that it was formulated with CPB-7 (contained 8 mole % of this acrylic acid repeat unit), instead of CPB-20 and gave a contact angle of 75°, despite both formulations having the same content of Joncryl 817. Similar effects were observed with the formulation which contained CPB copolymer with larger contents of acrylic acid repeat units. In all cases observed the increase in wettability led good lithographic performance with straight sidewalls like what was shown in FIG. 2 for Formulation 7.

Some slight dark erosion, which was less than 1 micron was observed for some of the samples with increased wettability, but this slight dark erosion did not deleteriously affect the imaging capability of these formulations.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. A positive working chemically amplified photosensitive composition comprising:
Component a) at least one random copolymer, having structure (A), wherein
the repeat unit of structure (I) ranges from about 17 mole % to about 70 mole %,
the repeat unit of structure (II) ranges from 0 to about 70 mole %,
the repeat unit of structure (III) ranges from 0 to about 70 mole %,
the sum of the repeat unit of structures (II) and (III) ranges from about 30 mole % to about 70 mole %,
the repeat unit of structure (IV) ranges from about 0 mole % to about 35 mole %, wherein the sum of the mole % of the repeat units of structure (I), (II), (III), and (IV) either does not exceed 100 mole % or is equal to 100 mole %, if other types of repeat units are not present, Ri₁, Ri₂, Ri₁₄ and Ri₁₃ are individually selected from H or a C-1 to C-4 alkyl, Ri₃, Ri₄, Ri₅, Ri₆, R₇, Ri₈, Ri₉, Ri₁₀, Ri₁₁, and Ri₁₂, are individually selected from H, a C-1 to C-8 alkyl, a C-1 to C-4 alkoxy, a phenyl, a substituted phenyl, and mixtures thereof, Li₁ is a C-2 to C-6 alkylene moiety, ni, mi, oi and pi are respectively the number of repeat units of structure (I), (II), (III) and (IV), and further wherein,
the copolymer of structure (A) has a minimum dissolution rate of 500 Å/sec in 0.26 N tetramethylammonium hydroxide at 23° C., and does not comprise any repeat units which have acid cleavable groups: 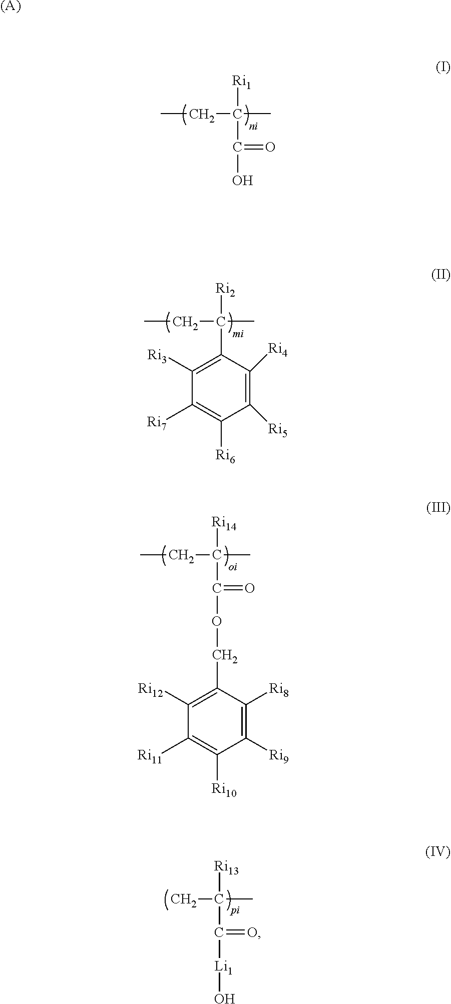
component b) at least one acrylic copolymer component of structure (B) comprising repeat units selected from ones having structure (1), (2), (3), (4), (5), (6), and (7): wherein
R₁, R₂, R₃, R₄, R₅, R₆, and R₇ are individually selected from either H, F, a C-1 to C-4 perfluoroalkyl, or a C-1 to C-4 alkyl,
R₈ and R₉ are individually selected from H, a C-1 to C-4 alkyl, a C-1 to C-4 alkyloxy alkyl, and a halogen,
R₁₀ is selected from the group consisting of a C-1 to C-8 primary alkyl, a C-3 to C-8 secondary alkyl, a C-3 to C-8 cyclic secondary alkyl, and a C-7 to C-14 secondary alicyclic alkyl,
R₁₁ is a C-2 to C-8 (hydroxy)alkylene moiety,
R₁₂ is a tertiary alkyl acid cleavable group, and
R₁₃ is a C-3 to C-12, (alkyloxy)alkylene moiety; and further
these repeat units in total constitute 100 mole % of the repeat units in said functionalized acrylic copolymer, wherein,
the repeat unit of structure (1) ranges from about 0 mole % to about 20 mole % of the acrylic copolymer,
the repeat unit of structure (2) ranges from about 0 mole % to about 20 mole % of the acrylic copolymer,
wherein the repeat unit of structure (3) ranges from about 5 mole % to about 55 mole % of the acrylic copolymer,
wherein the repeat unit of structure (4) ranges from about 0 mole % to about 30 mole % of the acrylic copolymer,
the repeat unit of structure (5) ranges from about 15 mole % to about 55 mole % of the acrylic copolymer,
the repeat unit of structure (6) ranges from about 18 mole % to about 40 mole % of the acrylic copolymer
the repeat unit of structure (7) ranges from about 0 mole % to about 40 mole % of the acrylic copolymer 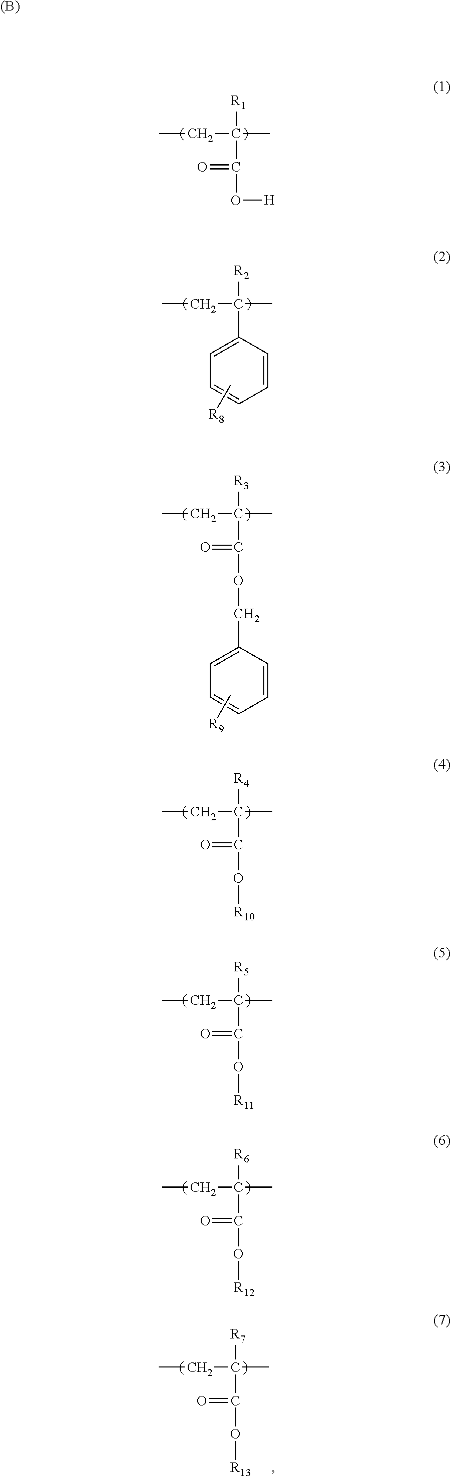
component c) at least one Novolak polymer,
component d) at least one photoacid generator (PAG),
component e) at least one base additive,
component f) at least one heterocyclic thiol compound,
component g) an organic spin casting solvent.

2. The composition of claim 1, wherein component a) is a copolymer consisting of repeat units of structure (I) and (II).

3. The composition of claim 1, wherein component a) is a copolymer consisting of repeat units of structure (I), and (III).

4. The composition of claim 1, wherein component a) is a copolymer consisting of the repeat units of structure (I), (II), and (III).

5. The composition of claim 1, wherein component a) is a copolymer consisting of repeat units of structure (I), (II) and (IV).

6. The composition of claim 1, wherein component a) is a copolymer consisting of repeat units of structure (I), (III) and (IV).

7. The composition of claim 1, wherein component a) is a copolymer consisting of the repeat units of structure (I), (II), (III) and (IV).

8. The composition of claim 1, wherein the repeat units of structure (I) ranges from about 20 mole % to about 65 mole %, of the total repeat units in the copolymer.

9. The composition of claim 1, wherein component a) has a structure selected from the group consisting of structure (A-1), structure (A-2), structure (A-3), structure (A-4), structure (A-5), structure (A-6), structure (A-7), structure (A-8), and structure (A-9),

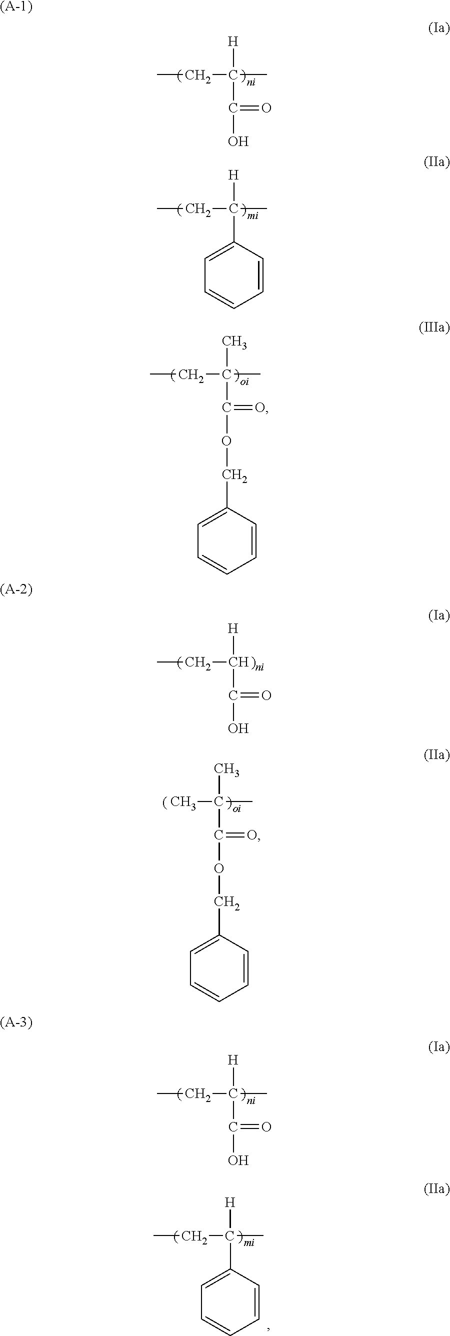

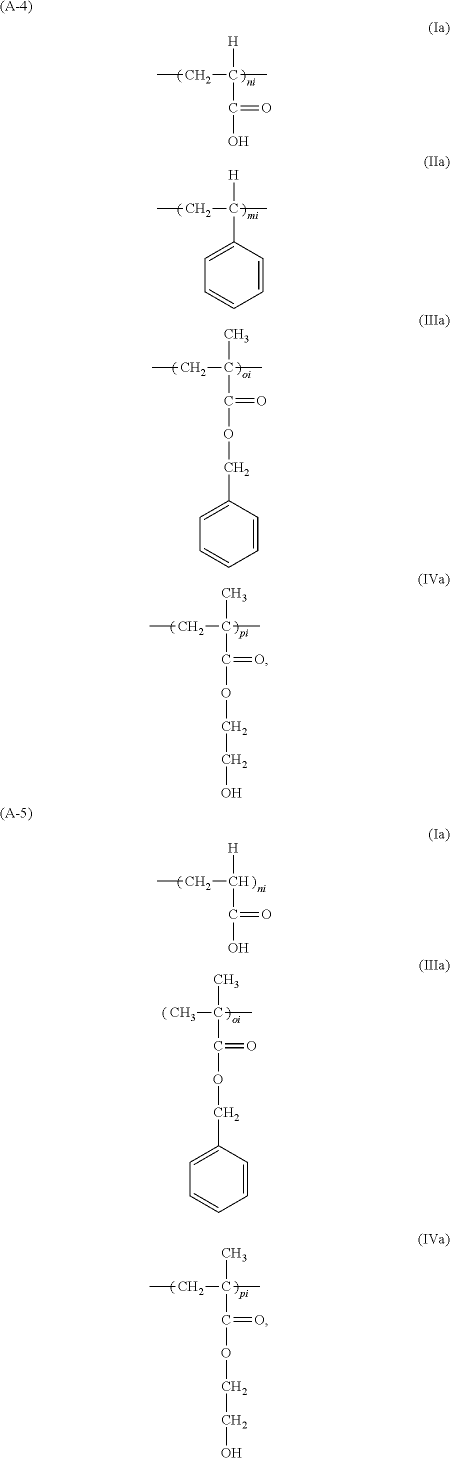

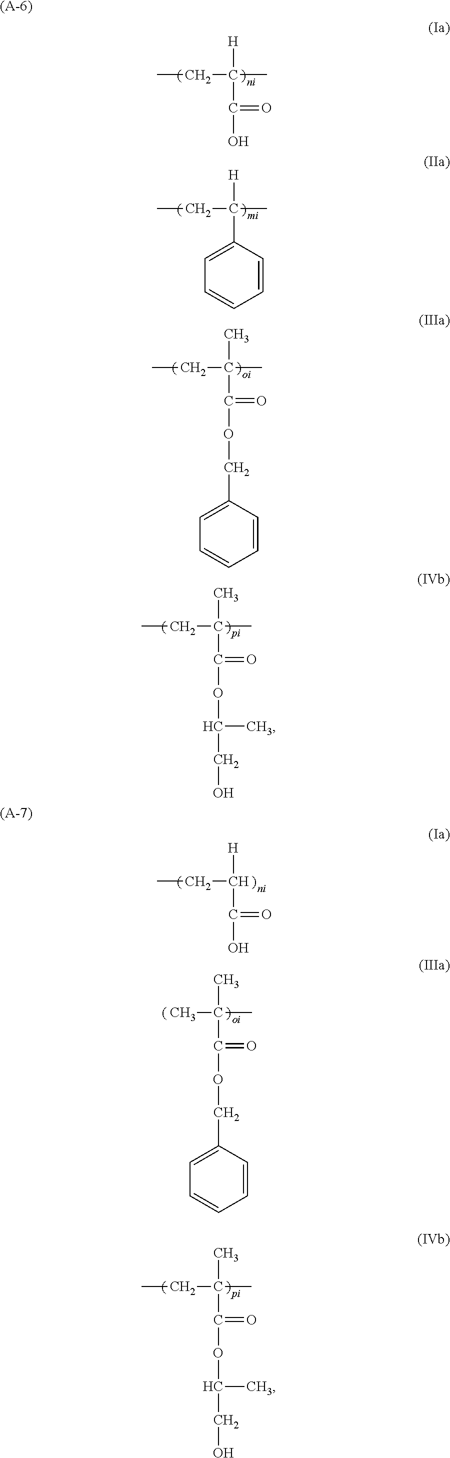

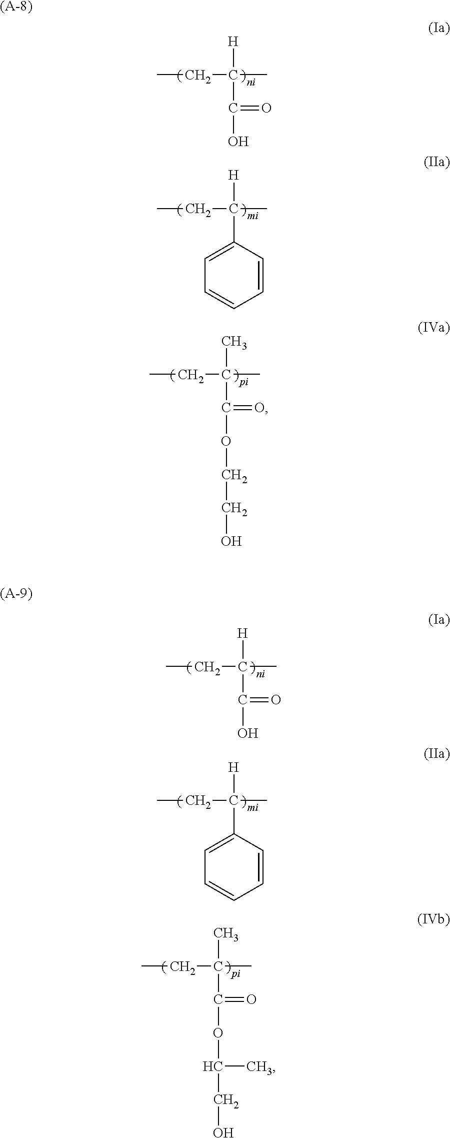

10-17. (canceled)

18. The composition of claim 1, wherein component a) ranges from about 10 wt. % to about 25 wt. % of total solid components.

19-20. (canceled)

21. The composition of claim 1, wherein component b) ranges from about 20 wt. % to about 65 wt. % of total solid components.

22-23. (canceled)

24. The composition of claim 1, wherein component b) comprises at least one copolymer of structure (B) which comprises from about 5 mole % to about 20 mole % of the repeat unit of structure (1).

25. The composition of claim 1, wherein component b) comprises at least one copolymer of structure (B) which comprises from about 5 mole % to about 20 mole % of the repeat unit of structure (7).

26. The composition of claim 1, wherein component b) comprises at least one copolymer of structure (B) in which the repeat unit of structure (1) ranges from about 5 mole % to about 20 mole % and the repeat unit of structure (7) ranges from about 5 mole % to about 20 mole %.

27. (canceled)

28. The composition of claim 1, wherein component b) comprises at least one copolymer of structure (B), where at least one said copolymer consists of from about 5 mole % to about 15 mole % of the repeat unit of structure (1), from about 15 mole % to about 25 mole % of the repeat unit of structure (3), from about 35 mole % to about 45 mole % of the repeat unit of structure (5), and from about 25 mole % to about 35 mole % of the repeat unit of structure (6).

29. The composition of claim 1, wherein component b) comprises at least one copolymer of structure (B), which consist from about 5 mole % to about 10 mole % of the repeat unit of structure (1), from about 15 mole % to about 25 mole % of the repeat unit of structure (3), from about 45 mole % to about 55 mole % of the repeat unit of structure (5), from about 15 mole % to about 25 mole % of the repeat unit of structure (6).

30. The composition of claim 1, wherein component b) comprises at least one copolymer of structure (B), where at least one said copolymer consists from about 5 mole % to about 10 mole % of the repeat unit of structure (1), from about 12 mole % to about 22 mole % of the repeat unit of structure (3), from about 20 mole % to about 35 mole % of the repeat unit of structure (5), about 25 mole % to about 40 mole % of the repeat unit of structure (6) and from about 5 mole % to about 15 mole % of the repeat unit of structure (7).

31. The composition of claim 1, wherein component b) comprises at least one copolymer of structure (B), where at least one said copolymer consists from about 12 mole % to about 22 mole % of the repeat unit of structure (3), from about 30 mole % to about 40 mole % of the repeat unit of structure (5), from about 25 mole % to about 40 mole % of the repeat unit of structure (6), and from about 5 mole % to about 15 mole % of the repeat unit of structure (7).

32. The composition of claim 1, wherein component b) comprises at least one copolymer of structure (B), where at least one said copolymer consists from about 5 mole % to about 8 mole % of the repeat unit of structure (1), from about 10 mole % to about 17 mole % of the repeat unit of structure (3), from about 30 mole % to about 40 mole % of the repeat unit of structure (5), from about 25 mole % to about 40 mole % of the repeat unit of structure (6), and from about 5 mole % to about 15 mole % of the repeat unit of structure (7).

33. The composition of claim 1, wherein component b) comprises at least one copolymer of structure (B), where at least one said copolymer consists from about 5 mole % to about 7.5 mole % of the repeat unit of structure (1), from about 10 mole % to about 17 mole % of the repeat unit of structure (3), from about 30 mole % to about 40 mole % of the repeat unit of structure (5), from about 25 mole % to about 40 mole % of the repeat unit of structure (6), and from about 5 mole % to about 15 mole % of the repeat unit of structure (7).

34. The composition of claim 1, wherein component b) comprises at least one copolymer of structure (B), where at least one said copolymer consists from about 5 mole % to about 15 mole % of the repeat unit of structure (1), from about 5 mole % to about 15 mole % of the repeat unit of structure (3), from about 30 mole % to about 40 mole % of the repeat unit of structure (5), from about 25 mole % to about 40 mole % of the repeat unit of structure (6), and from about 5 mole % to about 15 mole % of the repeat unit of structure (7).

35. The composition of claim 1, wherein component b) comprises at least one copolymer of structure (B), where at least one said copolymer consists from about 5 mole % to about 15 mole % of the repeat unit of structure (1), from about 20 mole % to about 35 mole % of the repeat unit of structure (3), from about 30 mole % to about 40 mole % of the repeat unit of structure (5), from about 15 mole % to about 25 mole % of the repeat unit of structure (6), and from about 5 mole % to about 15 mole % of the repeat unit of structure (7).

36. The composition of claim 1, wherein component b) comprises at least one copolymer of structure (B), where at least one said copolymer consists from about 5 mole % to about 15 mole % of the repeat unit of structure (1), from about 20 mole % to about 30 mole % of the repeat unit of structure (3), from about 35 mole % to about 45 mole % of the repeat unit of structure (5), from about 15 mole % to about 25 mole % of the repeat unit of structure (6), and from about 5 mole % to about 15 mole % of the repeat unit of structure (7).

37. The composition of claim 1, wherein component b) comprises at least one copolymer of structure (B), where at least one said copolymer consists from about 7 mole % to about 18 mole % of the repeat unit of structure (1), from about 15 mole % to about 25 mole % of the repeat unit of structure (3), from about 25 mole % to about 35 mole % of the repeat unit of structure (5), from about 15 mole % to about 25 mole % of the repeat unit of structure (6), and from about 5 mole % to about 15 mole % of the repeat unit of structure (7).

38. The composition of claim 1, wherein component b) comprises at least one copolymer of structure (B), where at least one said copolymer consists from about 7 mole % to about 15 mole % of the repeat unit of structure (1), from about 25 mole % to about 35 mole % of the repeat unit of structure (3), from about 25 mole % to about 35 mole % of the repeat unit of structure (5), from about 25 mole % to about 35 mole % of the repeat unit of structure (6).

39. The composition of claim 1, wherein component b) comprises at least one copolymer of structure (B), where at least one said copolymer consists from about 7 mole % to about 15 mole % of the repeat unit of structure (1), from about 27 mole % to about 45 mole % of the repeat unit of structure (3), from about 30 mole % to about 40 mole % of the repeat unit of structure (5), from about 15 mole % to about 25 mole % of the repeat unit of structure (6).

40. The composition of claim 1, wherein component b) comprises at least one copolymer of structure (B), where at least one said copolymer consists from about 7 mole % to about 15 mole % of the repeat unit of structure (1), from about 15 mole % to about 25 mole % of the repeat unit of structure (3), from about 35 mole % to about 45 mole % of the repeat unit of structure (5), from about 25 mole % to about 35 mole % of the repeat unit of structure (6).

41. The composition of claim 1, wherein component b) comprises at least one copolymer of structure (B), where at least one said copolymer consists from about 7 mole % to about 15 mole % of the repeat unit of structure (1), from about 20 mole % to about 37 mole % of the repeat unit of structure (3), from about 30 mole % to about 45 mole % of the repeat unit of structure (5), from about 20 mole % to about 30 mole % of the repeat unit of structure (6).

42. The composition of claim 1, wherein component b) comprises at least one copolymer of structure (B), where at least one said copolymer consists from about 7 mole % to about 15 mole % of the repeat unit of structure (1), from about 20 mole % to about 30 mole % of the repeat unit of structure (3), from about 30 mole % to about 45 mole % of the repeat unit of structure (5), from about 20 mole % to about 35 mole % of the repeat unit of structure (6).

43. The composition of claim 1, wherein component b) comprises at least one copolymer of structure (B), where at least one said copolymer consists from about 10 mole % to about 20 mole % of the repeat unit of structure (1), from about 20 mole % to about 30 mole % of the repeat unit of structure (3), from about 30 mole % to about 45 mole % of the repeat unit of structure (5), from about 20 mole % to about 35 mole % of the repeat unit of structure (6).

44-46. (canceled)

47. The composition of claim 1, wherein:
the repeat unit of structure (1), if present, has either structures (1a) or (1b), 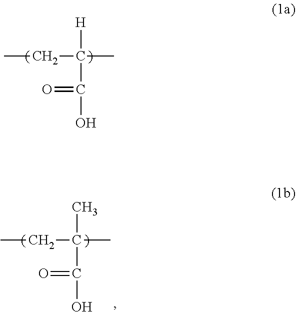
the repeat unit of structure (3) has either structures (3a) or (3b), 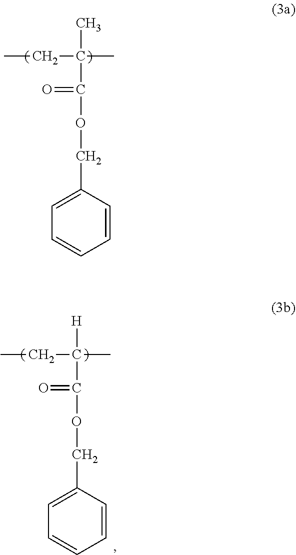
the repeat unit of structure (5) has either structures (5a) or (5b), 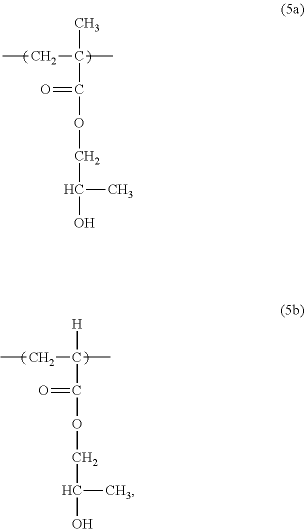
the repeat unit of structure (7), if present, has either structure (7a) or (7b), 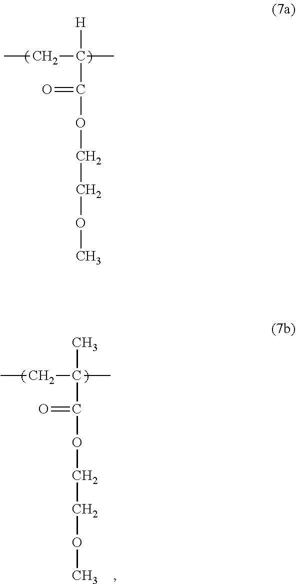
the repeat unit of structure (6), has either structures (6a), (6b), (6c) or (6d)

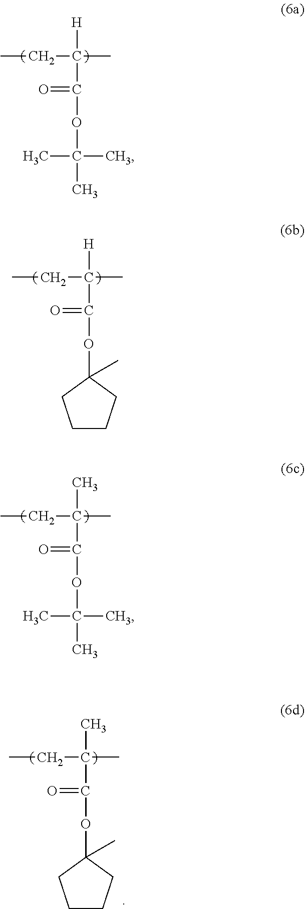

48-53. (canceled)

54. The composition of claim 1, wherein, component d), the photo acid generator (PAG) is an aromatic imide N-oxysulfonate derivative of an organic sulfonic acid, an aromatic sulfonium salt of an organic sulfonic acid, a trihalotriazine derivative or a mixture thereof.

55-58. (canceled)

59. The composition of claim 1, wherein, component f), said heterocyclic thiol is chosen from the general formulas: 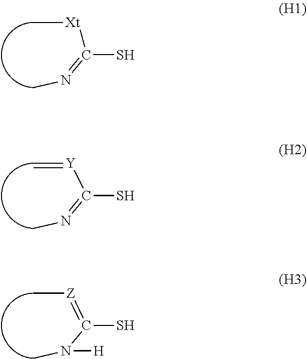
in said structure (H1), Xt is selected from the group consisting of N(Rt₃), C(Rt₁)(Rt₂), O, S, Se, and Te;
in said structure (H2), Y is selected from the group consisting of C(Rt₃) and N;
in said structure (H3), Z is selected from the group consisting of C(Rt₃) and N; and
Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms.

60-61. (canceled)

62. A process for imaging a resist comprising the steps;
i) coating the composition of claim 1 on a substrate to form a resist film;
ii) selectively exposing the resist film to UV light using a mask to form a selectively exposed resist film;
iii) developing the selectively exposed film to form a positively imaged resist film over the substrate.

63. The process of claim 62 for imaging a resist comprising the steps;
ia) coating the composition of claim 1 on a substrate to form a resist film;
iia) selectively exposing the resist film to UV light using a mask to form a selectively exposed resist film;
iiia) baking the selectively exposed resist film to form a baked selectively exposed resist film;
iva) developing the selectively exposed and baked resist film to form a positively imaged resist film over the substrate.

64. (canceled)
